(19) United States
(12) Patent Application Publication
(10) Pub. No.: US 2026/0199995 A1
(43) Pub. Date: Jul. 16, 2026

(54) WIRE ELECTRICAL DISCHARGE MACHINING APPARATUS, WIRE ELECTRICAL DISCHARGE MACHINING METHOD, AND WAFER MANUFACTURING METHOD

(71) Applicant: Mitsubishi Electric Corporation, Tokyo (JP)

(72) Inventor: Hidetaka MIYAKE, Tokyo (JP)

(73) Assignee: Mitsubishi Electric Corporation, Tokyo (JP)

(21) Appl. No.: 18/867,814

(22) PCT Filed: Jun. 17, 2022
(86) PCT No.: PCT/JP2022/024397

§ 371 Date: Nov. 21, 2024

(51) Int. Cl. B23H 7/04; B23H 1/10; B23H 11/00; H10P 54/92

(52) U.S. Cl. CPC B23H 7/04; B23H 1/10; B23H 11/003; H10P 54/922

(57) ABSTRACT

A wire electrical discharge machining apparatus includes a pair of machining fluid flow rectifying plates having conductivity and is in contact with both sides of a workpiece so as to sandwich the workpiece. There is a pair of nozzles ejecting a machining fluid toward a space sandwiched between the pair of machining fluid flow rectifying plates to supply the machining fluid to a gap between the plurality of cutting wire parts and the workpiece, and a cutting feed stage that moves the pair of machining fluid flow rectifying plates upward and downward relative to the plurality of cutting wire parts. Further, the apparatus includes a workpiece retaining unit that holds the workpiece to be divided during cutting from above the workpiece and the plurality of cutting wire parts, and a lower workpiece holding portion having conductivity that comes into contact with the workpiece from below to hold the workpiece.

### FIELD

The present disclosure relates to a wire electrical discharge machining apparatus that performs electrical discharge machining in which a plurality of plate members are collectively cut out from a workpiece using a wire electrode, a wire electrical discharge machining method, and a wafer manufacturing method.

### BACKGROUND

In a multi-wire electrical discharge machining apparatus, electrical discharge is generated between a plurality of wire electrodes and a workpiece, and a plurality of plate members are collectively cut out from the workpiece. In simultaneous cutting of the plurality of plate members by electrical discharge machining, a plurality of grooves are formed in the workpiece at positions corresponding to wire cutting parts which are a plurality of portions of the wire electrodes. Then, the wire cutting parts each enter corresponding one of the plurality of grooves, which provides deeper grooves. Then, when the grooves come to reach an edge of the workpiece, a plurality of thin plates are simultaneously generated.

Heat energy and machining debris resulting from electrical discharge are constantly generated between the thin plates being generated, that is, in a machining gap during electrical discharge machining. Both of the heat energy and the machining debris resulting from the electrical discharge are factors in unstable electrical discharge machining. Therefore, for the purpose of evacuation of machining debris and inter-electrode cooling, an attempt is made to supply a machining fluid from a machining fluid supply device to between electrodes via a machining fluid nozzle to eliminate a machining destabilizing element, and in order to appropriately supply the machining fluid to between the electrodes, the machining fluid nozzle is disposed as close to the workpiece as possible so that the machining fluid is appropriately supplied to between the electrodes.

For example, Patent Literature 1 discloses a configuration in which in a wire electrical discharge machining apparatus that machines a workpiece by applying a voltage to a gap formed between a wire electrode and the workpiece in a machining fluid and generating electrical discharge, with respect to heat energy and machining debris resulting from the electrical discharge which are generated in a machining gap during electrical discharge machining, a machining fluid is supplied from a machining fluid supply device to between electrodes via a machining fluid nozzle for the purpose of inter-electrode cooling and evacuation of the machining debris, and the machining fluid nozzle is brought as close to the workpiece as possible in order to appropriately supply the machining fluid to between the electrodes.

Patent Literature 2 discloses a holding device in electrical discharge machining in which an ingot is sliced at an interval at which wires are arranged in parallel, the holding device including a holding unit that holds the ingot and an energization unit that energizes the ingot so that a current flows through the ingot. An object of this holding device is as follows: while holding the ingot so as not to fall, in a region where electrical discharge machining proceeds, a region is eliminated where electrical discharge machining proceeds in the presence of both the ingot holding unit and the ingot made of different materials, to thereby reduce instability of electrical discharge machining due to simultaneous electrical discharge on those made of different materials, prevent wire breakage, and stabilize machining.

### CITATION LIST

### Patent Literature

Patent Literature 1: WO 2020/213040 A1
Patent Literature 2: Japanese Patent Application Laid-open No. 2015-120235

### SUMMARY OF INVENTION

### Problem to be Solved by the Invention

In Patent Literature 1, a method for fixing a workpiece includes increasing a contact area with a cut-out end face fixing block installed on a jig plate, and increasing a holding force against shaking of each thin plate under working process, and the workpiece is fixed with a conductive adhesive or the like by using an orientation flat portion of the workpiece. In addition, energization from the cut-out end face fixing block can be performed so that a power supply path to the workpiece should not be interrupted until cutting into the thin plates is completed. However, if the workpiece is merely fixed only at a machining end portion, when the diameter of thin plates to be machined increases, it is necessary to greatly reduce the flow rate of a machining fluid in order to prevent cracking of the thin plates, and there is a possibility that an electrical discharge machining speed rapidly decreases due to defective evacuation of machining debris or insufficient wire cooling.

In Patent Literature 2, electrical discharge machining is performed while lowering a workpiece toward a wire electrode, and therefore it is considered that, due to a decrease in flexural rigidity of each thin plate due to an increase in diameter, the weight of the thin plate itself has less influence. However, in a case where the method of Patent Literature 2 is applied to Patent Literature 1, such application results in a structure in which deflection of the thin plates due to pressure of a machining fluid flow is reduced by one holding unit and two wafer retainers which face each other. In particular, such a wafer retainer is made of a urethane or sponge-like material, and when receiving a strong machining fluid flow, the material itself deforms slides with respect to outer peripheral surfaces of the thin plates, and is disposed so that the thin plates are pressed at a position away from cutting end portions of the thin plates, and therefore it is difficult to prevent cracking at the end of cutting due to deflection of the thin plates having a large diameter.

The present disclosure has been made in view of the above, and an object thereof is to provide a wire electrical discharge machining apparatus capable of preventing damage to thin plates when the thin plates are cut out.

### Means to Solve the Problem

In order to solve the above-described problems and achieve the object, a wire electrical discharge machining apparatus according to the present disclosure is a wire electrical discharge machining apparatus that generates electrical discharge between a plurality of cutting wire parts that are running and a workpiece to perform electrical discharge machining on the workpiece with energy generated by the electrical discharge, and simultaneously cuts a plurality of wafers from the workpiece. The wire electrical discharge machining apparatus includes a wire electrode including the plurality of cutting wire parts spaced apart from each other in parallel and facing the workpiece; a power feed unit that generates electrical discharge between the plurality of cutting wire parts and the workpiece; a pair of machining fluid flow rectifying plates having conductivity connected to a power supply and provided in contact with both sides of the workpiece so as to sandwich the workpiece; and a pair of nozzles in which the plurality of cutting wire parts are inserted, the pair of nozzles including a plurality of machining fluid ejection holes that eject a machining fluid toward a space sandwiched between the pair of machining fluid flow rectifying plates to supply the machining fluid to a gap between the plurality of cutting wire parts and the workpiece. The wire electrical discharge machining apparatus includes a cutting feed stage that moves the pair of machining fluid flow rectifying plates upward and downward relative to the plurality of cutting wire parts; a workpiece retaining unit that holds the workpiece to be divided during cutting from above the workpiece and the plurality of cutting wire parts; and a lower workpiece holding portion having conductivity that comes into contact with the workpiece from below to hold the workpiece.

### Effects of the Invention

A wire electrical discharge machining apparatus according to the present disclosure achieves an effect that it is possible to prevent damage to thin plate when the thin plates are cut out.

### BRIEF DESCRIPTION OF DRAWINGS

FIG. 1 is a conceptual diagram illustrating an exemplary configuration of a wire electrical discharge machining apparatus according to a first embodiment.

FIG. 2 is a perspective view illustrating a thin plate machining stabilization unit included in the wire electrical discharge machining apparatus according to the first embodiment, and a positional relationship between the thin plate machining stabilization unit and mechanisms around the thin plate machining stabilization unit.

FIG. 3 is a cross-sectional view illustrating an internal configuration of the thin plate machining stabilization unit included in the wire electrical discharge machining apparatus according to the first embodiment.

FIG. 4 is a diagram illustrating a supply path of an electrical discharge machining power supply from a machining power supply to a workpiece in the wire electrical discharge machining apparatus according to the first embodiment.

FIG. 5 is a block diagram illustrating an exemplary configuration of a control unit included in the wire electrical discharge machining apparatus according to the first embodiment.

FIG. 6 is a flowchart illustrating an operation of the wire electrical discharge machining apparatus according to the first embodiment during cutting.

FIG. 7 is a first perspective view illustrating a state of thin plates during cutting in the thin plate machining stabilization unit included in the wire electrical discharge machining apparatus according to the first embodiment.

FIG. 8 is a second perspective view illustrating the state of the thin plates during the cutting in the thin plate machining stabilization unit included in the wire electrical discharge machining apparatus according to the first embodiment.

FIG. 9 is a set of diagrams for explaining a relationship between a cutting position and a cutting length of the workpiece during cutting by the wire electrical discharge machining apparatus according to the first embodiment.

FIG. 10 is a schematic view illustrating an exemplary configuration of a workpiece power feed assistance portion included in a wire electrical discharge machining apparatus according to a second embodiment.

FIG. 11 is a conceptual diagram illustrating an example of a state of the thin plates immediately before the completion of cutting in the wire electrical discharge machining apparatus according to the first embodiment.

FIG. 12 is an enlarged view illustrating a specific region in FIG. 11.

FIG. 13 is a conceptual diagram illustrating an example of a state of thin plates immediately before the completion of cutting in the wire electrical discharge machining apparatus according to the second embodiment.

FIG. 14 is an enlarged view illustrating a specific region in FIG. 13.

FIG. 15 is a schematic view illustrating an exemplary configuration of thin plate side surface holding portions of a thin plate machining stabilization unit included in a wire electrical discharge machining apparatus according to a third embodiment.

FIG. 16 is an enlarged view illustrating a specific region in FIG. 15.

FIG. 17 is another enlarged view illustrating the specific region in FIG. 15.

FIG. 18 is a diagram illustrating a hardware configuration in a case where functions of the control unit included in each of the wire electrical discharge machining apparatuses are realized by dedicated hardware.

FIG. 19 is a diagram illustrating a hardware configuration in a case where the functions of the control unit included in each of the wire electrical discharge machining apparatuses illustrated in FIG. 18 are realized by a processor that executes a program stored in a memory.

### DESCRIPTION OF EMBODIMENTS

Hereinafter, a wire electrical discharge machining apparatus, a wire electrical discharge machining method, and a wafer manufacturing method according to each embodiment will be described in detail with reference to the drawings.

### First Embodiment

A multi-wire electrical discharge machining apparatus is used, for example, in a semiconductor manufacturing step, for slicing in which a plurality of semiconductor wafers are collectively cut out from an ingot, that is, collective cutting of the plurality of semiconductor wafers. As the collective cutting proceeds, thin plates in the process of the collective cutting are cut from the ingot, a thin plate portion which is to be semiconductor wafers increases, and a portion integrated with the ingot decreases. Then, immediately before the collective cutting is completed, adjacent thin plates are in a state of being connected to each other only via a small remaining machining portion which has not yet been machined.

The thin plates in that state are shaken by a flow of a machining fluid supplied to between electrodes, i.e., a gap between the ingot and a wire, or, specifically, for example, when a thin plate has a diameter of 6 inches or more, combined with the influence of the weight of the thin plate itself, there occurs deflection of the thin plate. As a result, particularly in a thin plate having a large diameter with respect to a plate thickness, stress due to deflection is concentrated in the vicinity of a remaining machining portion, and cracking starting from the remaining machining portion is likely to occur. Even with high hardness materials having relatively high hardness, such as silicon carbide (Sic) and gallium nitride (GaN), when the diameter of a semiconductor wafer with respect to the thickness thereof increases, the semiconductor wafer shakes or deflects due to a decrease in rigidity of the semiconductor wafer itself or due to a force received from the machining fluid flow.

In the case of a semiconductor wafer, cracking or chipping that occurs even in a part of the semiconductor wafer results in a problem such as a decrease in production yield in a polishing step of a sliced semiconductor wafer or a semiconductor manufacturing process after the polishing step. Therefore, cracking or chipping of a semiconductor wafer is a factor in significant impairment of a commercial value of the semiconductor wafer.

That is, in electrical discharge machining in which a plurality of plate members are collectively cut from a workpiece by using a wire electrode, in order to improve evacuation of machining debris generated by electrical discharge and cooling of a wire heated by electrical discharge energy, a flow rate of a machining fluid supplied to a gap between the thin plates under cutting process is increased, the thin plates are shaken due to an increase in pressure of the machining fluid flow received by a thin plate portion, and each thin plate under cutting process gradually becomes prone to bend because of a decrease in bending rigidity of the thin plate itself due to an increase in diameter with respect to a thickness of the thin plate.

Then, the pressure of the machining fluid flow acts on the thin plates, and stress concentration occurs at the boundary between the formed thin plate portion and the remaining machining portion of the workpiece or in the vicinity of a portion where cutting into the thin plates is about to be completed, so that cracking or chipping is likely to occur in the thin plates. For example, in a case where the workpiece is an ingot made of a crystal of Sic or GaN, as a diameter increases and a diameter dimension of a semiconductor wafer increases, the influence of fluid pressure that a thin plate portion receives from a machining fluid flow during electrical discharge machining or the influence of a decrease in rigidity becomes significant.

Hereinafter, not only a thin plate cut off by cutting is referred to as a wafer, but also a workpiece in which a machined groove is formed, that is, a thin plate-like portion which is a part of the workpiece and is not cut off yet is referred to as “a wafer”, “a wafer being machined”, or the like.

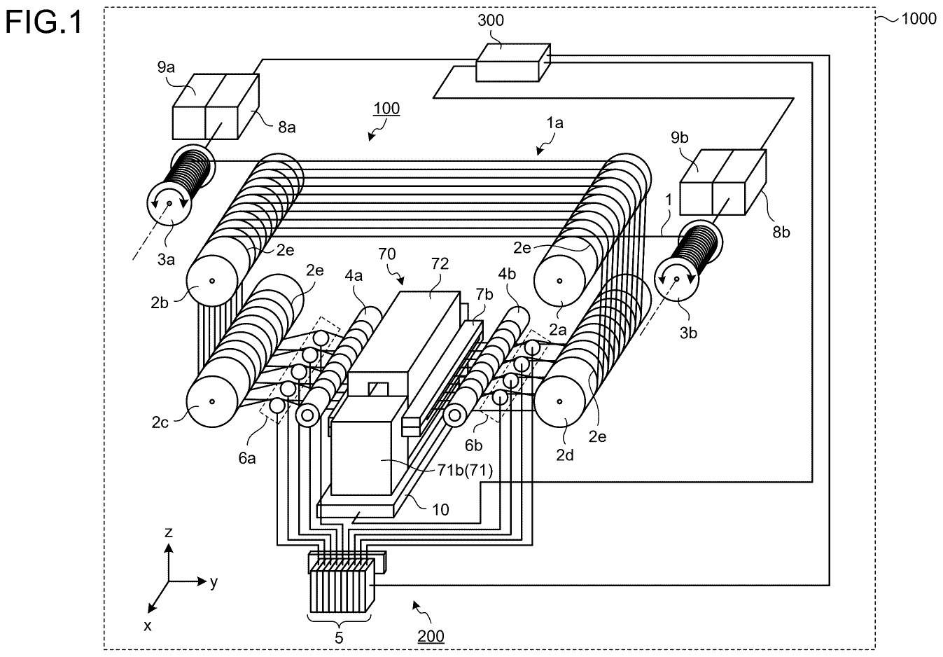

FIG. 1 is a conceptual diagram illustrating an exemplary configuration of a wire electrical discharge machining apparatus 1000 according to a first embodiment.

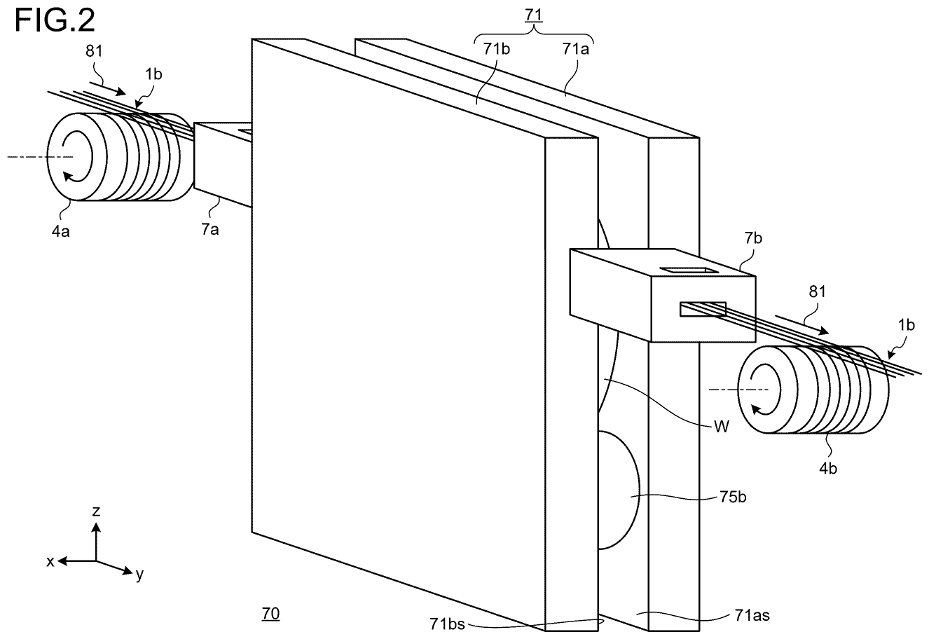

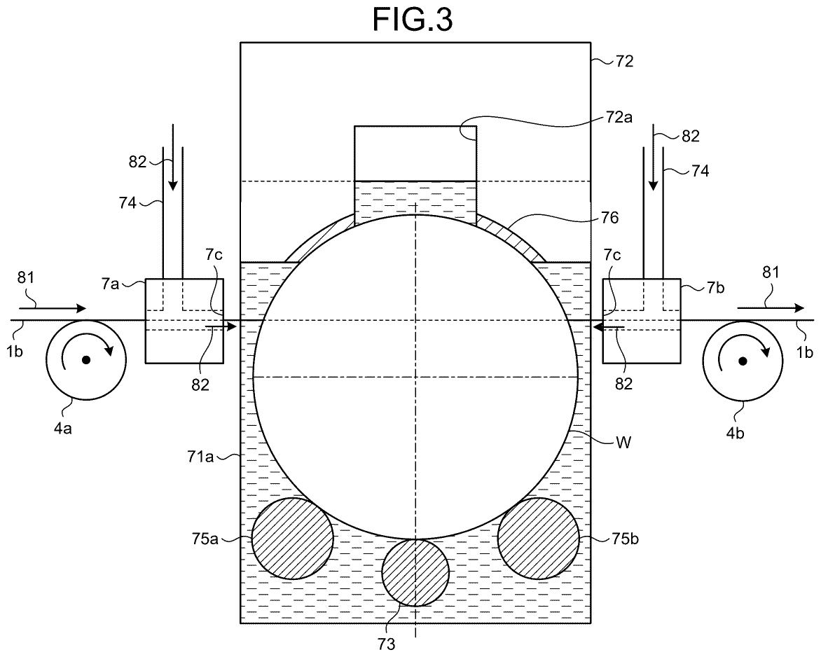

FIG. 2 is a perspective view illustrating a thin plate machining stabilization unit 70 included in the wire electrical discharge machining apparatus 1000 according to the first embodiment, and a positional relationship between the thin plate machining stabilization unit 70 and mechanisms around the thin plate machining stabilization unit 70. FIG. 3 is a cross-sectional view illustrating an internal configuration of the thin plate machining stabilization unit 70 included in the wire electrical discharge machining apparatus 1000 according to the first embodiment. FIG. 3 illustrates a state where wire electrical discharge machining has proceeded to a position corresponding to about ⅓ of a total machining distance with respect to a workpiece W installed on a machining fluid flow rectifying plate 71. FIG. 3 illustrates a cross section at a position between a machining fluid flow rectifying plate 71a and a machining fluid flow rectifying plate 71b to be described later. The wire electrical discharge machining apparatus 1000 is a multi-wire electrical discharge machining apparatus that performs electrical discharge machining by using a wire electrode 1. In FIGS. 2 and 3, each arrow 81 indicates a running direction of cutting wire parts 1b. In FIG. 3, each arrow 82 indicates a direction of a machining fluid flow.

FIG. 1 illustrates an x axis, a y axis, and a z axis of a three-axis Cartesian coordinate system. A y-axis direction corresponds to a running direction of the wire electrode 1 on the workpiece W, that is, the running direction of the wire electrode 1 with respect to the workpiece W disposed in the wire electrical discharge machining apparatus 1000. A z-axis direction corresponds to a height direction of the wire electrical discharge machining apparatus 1000. The height direction of the wire electrical discharge machining apparatus 1000 corresponds to an upward and downward direction, that is, a vertical direction. An x-axis direction corresponds to a direction in which portions of the wire electrode 1 are disposed in parallel to one another on the workpiece W, that is, a direction in which the portions of the wire electrode 1 are disposed in parallel to one another with respect to the workpiece W disposed in the wire electrical discharge machining apparatus 1000. The x-axis direction can be said to be a direction parallel to a longitudinal direction of the workpiece W disposed in the wire electrical discharge machining apparatus 1000.

The wire electrical discharge machining apparatus 1000 includes a machining mechanism unit 100 that performs electrical discharge cutting on the workpiece W with the wire electrode 1, a power feed unit 200 that executes power feeding, and a control unit 300 that controls the wire electrical discharge machining apparatus 1000. The wire electrical discharge machining apparatus 1000 cuts out a plurality of plate members collectively from the workpiece W. Examples of the material for the workpiece W include tungsten, molybdenum, silicon carbide, monocrystalline silicon, monocrystalline silicon carbide, gallium nitride, and polycrystalline silicon. Silicon carbide may be referred to as “tanka-keiso” in Japanese. Hereinafter, the electrical discharge cutting may be simply referred to as cutting.

The machining mechanism unit 100 includes a plurality of guide rollers 2, bobbins 3, damping guide rollers 4a and 4b, nozzles 7a and 7b, bobbin rotation control devices 8a and 8b, traverse control devices 9a and 9b, and a cutting feed stage 10. The plurality of guide rollers 2 include a guide roller 2a, a guide roller 2b, a guide roller 2c, and a guide roller 2d. The bobbins 3 include a bobbin 3a and a bobbin 3b.

The plurality of guide rollers 2 guide the running of the wire electrode 1. Each of the guide rollers 2a, 2b, 2c, and 2d is installed so as to be rotatable around a rotation axis corresponding thereto. The guide rollers 2a, 2b, 2c, and 2d are disposed apart from one another, and are disposed so that rotation axes thereof are parallel to one another. Since the rotation axes of the guide rollers 2a, 2b, 2c, and 2d are parallel to one another, the wire electrode 1 can run with high accuracy. The rotation axes of the guide rollers 2a, 2b, 2c, and 2d are disposed parallel to the x axis.

One wire electrode 1 is wound a plurality of times around the guide rollers 2a, 2b, 2c, and 2d at intervals in a direction of the rotation axis of each of the guide rollers 2a, 2b, 2c, and 2d. These portions of the wire electrode 1 are collectively referred to as parallel wire parts 1a. Portions of the parallel wire parts 1a facing the workpiece W are each referred to as a cutting wire part 1b. The cutting wire parts 1b include a plurality of portions of the wire electrode 1 disposed in parallel. The cutting wire parts 1b are preferably installed in parallel to one another.

On the surfaces of the guide rollers 2a, 2b, 2c, and 2d, a plurality of guide grooves 2e are formed at equal intervals. By winding the wire electrode 1 around the surfaces of the guide rollers 2a, 2b, 2c, and 2d along the plurality of guide grooves 2e, the guide rollers 2a, 2b, 2c, and 2d keep the interval between the portions of the wire electrode 1, that is, the interval between the portions of the wire electrode 1 of the parallel wire parts 1a constant. In the wire electrical discharge machining apparatus 1000, the cutting wire parts 1b are disposed in parallel to one another and at equal intervals, so that the plate thicknesses of the plurality of plate members cut out from the workpiece W can be made equal to one another, and the cross sections of the plurality of plate members can be made parallel to one another. Regarding the plurality of guide rollers 2, the number thereof is not necessarily four, and may be three or less, or may be five or more.

The bobbins 3a and 3b cause the wire electrode 1 to run by an operation of unwinding the wire electrode 1 and an operation of winding the wire electrode 1. The bobbin 3a performs the operation of unwinding the wire electrode 1. The bobbin 3b performs the operation of winding the wire electrode 1. The bobbin rotation control device 8a and the traverse control device 9a control the bobbin 3a. The bobbin rotation control device 8b and the traverse control device 9b control the bobbin 3b.

The bobbin rotation control device 8a controls the rotation of the bobbin 3a and controls the running of the wire electrode 1. The bobbin rotation control device 8a controls, for example, a running direction and a running speed of the wire electrode 1. The bobbin rotation control device 8b controls the rotation of the bobbin 3b and controls the running of the wire electrode 1. The bobbin rotation control device 8b controls, for example, the running direction and the running speed of the wire electrode 1.

The traverse control device 9a controls a position of the bobbin 3a in the x-axis direction correspondingly to an unwinding position of the wire electrode 1. The traverse control device 9b controls a position of the bobbin 3b in the x-axis direction correspondingly to a winding position of the wire electrode 1. The position control of the bobbins 3a and 3b by the traverse control devices 9a and 9b is referred to as traverse control. By the traverse control, the bobbins 3a and 3b can cause the wire electrode 1 to run stably and with high accuracy.

The wire electrode 1 unwound from the bobbin 3a is wound around the guide roller 2b, the guide roller 2a, the guide roller 2d, and the guide roller 2c in this order, and then the winding is continued from the guide roller 2b again. The wire electrode 1 is wound on to the bobbin 3b after circulating a plurality of times through the guide rollers 2a, 2b, 2c, and 2d in the manner as described above.

The workpiece W is fixed inside the thin plate machining stabilization unit 70. The thin plate machining stabilization unit 70 will be described in detail later. The thin plate machining stabilization unit 70 in which the workpiece W is fixed is installed between the damping guide roller 4a and the damping guide roller 4b. The damping guide rollers 4a and 4b restrict the movement of the wire electrode 1 in the z-axis direction, and thereby vibration of the wire electrode 1 in the cutting wire parts 1b is reduced. Although it has been described above that the portions of the parallel wire parts 1a facing the workpiece W are each referred to as the cutting wire part 1b, the portions of the parallel wire parts 1a between the damping guide roller 4a and the damping guide roller 4b are also each referred to as the cutting wire part 1b. In the wire electrical discharge machining apparatus 1000, the damping guide roller 4a and the damping guide roller 4b can be omitted.

The nozzle 7a is disposed between the damping guide roller 4a and the thin plate machining stabilization unit 70. The nozzle 7b is disposed between the damping guide roller 4b and the thin plate machining stabilization unit 70. The inside of the nozzles 7a and 7b is filled with the machining fluid supplied from a machining fluid supply pipe 74. The nozzles 7a and 7b include a plurality of machining fluid ejection holes 7c through which the machining fluid filled in the nozzles 7a and 7b is ejected toward the workpiece W in the thin plate machining stabilization unit 70. The parallel wire parts 1a run while being inserted in the plurality of machining fluid ejection holes 7c of the nozzles 7a and 7b.

The cutting feed stage 10 changes relative positions of the workpiece W and the cutting wire parts 1b. Specifically, the cutting feed stage 10 changes relative positions of the thin plate machining stabilization unit 70 in which the workpiece W is installed and fixed and the cutting wire parts 1b. In the first embodiment, it is assumed that the positions of the cutting wire parts 1b in the z-axis direction are fixed, and the cutting feed stage 10 is movable in the z-axis direction. The cutting feed stage 10 moves components inside the thin plate machining stabilization unit 70 in the upward and downward direction together with the workpiece W. By the movement of the cutting feed stage 10 in the upward and downward direction, the wire electrical discharge machining apparatus 1000 causes the workpiece W installed in the thin plate machining stabilization unit 70 to relatively approach or separate from the cutting wire parts 1b, thereby cutting the workpiece W. In addition, a machined groove Wg to be described later along each of the cutting wire parts 1b is formed in the workpiece W by the electrical discharge machining on the workpiece W. Note that the cutting feed stage 10 may be movable in the x-axis direction, the y-axis direction, and the z-axis direction.

The machining mechanism unit 100 may include components such as a guide pulley that reduces vibration of the wire electrode 1, a load cell that measures tension of the wire electrode 1, and a dancer roller that controls tension of the wire electrode 1. The machining mechanism unit 100 may maintain the tension of the wire electrode 1 in a range suitable for running of the wire electrode 1 by the load cell and the dancer roller. For example, the dancer roller may control the tension of the wire electrode 1 by changing an unwinding speed and a winding speed of the wire electrode 1.

The power feed unit 200 includes a machining power supply 5 and power feed contact units 6a and 6b. The machining power supply 5 supplies power to the wire electrode 1 via the power feed contact units 6a and 6b. The machining power supply 5 also supplies power to the workpiece W via the machining fluid flow rectifying plate 71a.

The thin plate machining stabilization unit 70 is a mechanism unit that prevents power supply failure to each thin plate during cutting. The thin plate machining stabilization unit 70 is disposed between the damping guide roller 4a and the damping guide roller 4b and between the nozzle 7a and the nozzle 7b. The thin plate machining stabilization unit 70 includes the machining fluid flow rectifying plate 71a and the machining fluid flow rectifying plate 71b which are a pair of machining fluid flow rectifying plates 71, a workpiece retaining unit 72, a workpiece power feed assistance portion 73, thin plate side surface holding portions 75a and 75b, and a workpiece retaining unit holding device 78 to be described later.

The machining fluid flow rectifying plate 71a and the machining fluid flow rectifying plate 71b which are the pair of machining fluid flow rectifying plates 71 have conductivity, are disposed in parallel to the running direction of the cutting wire parts 1b, and rectify the flow of the machining fluid. The machining fluid flow rectifying plate 71a and the machining fluid flow rectifying plate 71b are disposed between the nozzle 7a and the nozzle 7b. The machining fluid flow rectifying plate 71a and the machining fluid flow rectifying plate 71b have a plate shape or a rectangular parallelepiped shape, and are disposed so that surfaces thereof that face each other are parallel. That is, a facing surface 71as which is a surface of the machining fluid flow rectifying plate 71a facing the machining fluid flow rectifying plate 71b and a facing surface 71bs which is a surface of the machining fluid flow rectifying plate 71b facing the machining fluid flow rectifying plate 71a are parallel. The facing surface 71as of the machining fluid flow rectifying plate 71a and the facing surface 71bs of the machining fluid flow rectifying plate 71b are parallel to the running direction of the cutting wire parts 1b. The facing surface 71as and the facing surface 71bs are, for example, vertical surfaces.

The machining fluid flow rectifying plate 71a is a first machining fluid flow rectifying plate of the pair of machining fluid flow rectifying plates 71, and is connected to the machining power supply 5. Therefore, the electrical discharge machining power is supplied from the machining power supply 5 to the workpiece W, the workpiece power feed assistance portion 73, and the thin plate side surface holding portions 75a and 75b via the machining fluid flow rectifying plate 71a. Consequently, the supply of the electrical discharge machining power to the workpiece W is performed not only by the power supply to the workpiece W from the machining fluid flow rectifying plate 71a in contact with an end surface of the workpiece W, but also by the power supply to the workpiece W from the workpiece power feed assistance portion 73 and the thin plate side surface holding portions 75a and 75b which are in contact with the machining fluid flow rectifying plate 71a.

The machining fluid flow rectifying plate 71b is a second machining fluid flow rectifying plate of the pair of machining fluid flow rectifying plates 71, and is disposed in parallel to the machining fluid flow rectifying plate 71a in a state where the workpiece W, the workpiece power feed assistance portion 73, and the thin plate side surface holding portions 75a and 75b fixed to the machining fluid flow rectifying plate 71a are sandwiched between the machining fluid flow rectifying plate 71a and the machining fluid flow rectifying plate 71b. That is, the workpiece W, the workpiece power feed assistance portion 73, and the thin plate side surface holding portions 75a and 75b fixed to the machining fluid flow rectifying plate 71a are sandwiched between the facing surface 71as of the machining fluid flow rectifying plate 71a and the facing surface 71bs of the machining fluid flow rectifying plate 71b which are disposed in parallel to each other.

The machining fluid flow rectifying plate 71b is in close contact with the workpiece W, and forms, together with the machining fluid flow rectifying plate 71a, a flow path for guiding the machining fluid supplied from the nozzles 7a and 7b to the workpiece W. The machining fluid is supplied from the nozzles 7a and 7b to a gap between the machining fluid flow rectifying plate 71a and the machining fluid flow rectifying plate 71b, toward the workpiece W. The machining fluid ejected from the plurality of machining fluid ejection holes 7c of the nozzles 7a and 7b is guided to the workpiece W by the facing surface 71as of the machining fluid flow rectifying plate 71a and the facing surface 71bs of the machining fluid flow rectifying plate 71b. That is, the facing surface 71as of the machining fluid flow rectifying plate 71a and the facing surface 71bs of the machining fluid flow rectifying plate 71b regulate the flow of the machining fluid supplied to the gap between the machining fluid flow rectifying plate 71a and the machining fluid flow rectifying plate 71b in the x-axis direction, and form a flow path that guides the flow of the machining fluid to the workpiece W.

Consequently, the diffusion of the machining fluid in the thickness direction of the thin plates under cutting process, that is, in the x-axis direction is reduced. The cutting wire parts 1b run while being inserted in the plurality of machining fluid ejection holes 7c of the nozzles 7a and 7b. Consequently, the machining fluid easily enters a gap between the cutting wire parts 1b and the workpiece W.

In the wire electrical discharge machining apparatus 1000, since the flow of the machining fluid supplied from the nozzles 7a and 7b is rectified as described above, the diffusion of the machining fluid is reduced, which decreases a risk that the thin plates under cutting process are shaken by the machining fluid and cracked.

The workpiece W is sandwiched between the machining fluid flow rectifying plate 71a and the machining fluid flow rectifying plate 71b, and is fixed inside the thin plate machining stabilization unit 70. That is, the workpiece W is sandwiched between the facing surface 71as of the machining fluid flow rectifying plate 71a and the facing surface 71bs of the machining fluid flow rectifying plate 71b, and is fixed to the facing surface 71as of the machining fluid flow rectifying plate 71a. With an axial direction of the columnar shape of the workpiece W perpendicular to the facing surface 71as of the machining fluid flow rectifying plate 71a and the facing surface 71bs of the machining fluid flow rectifying plate 71b, one end surface of the columnar shape of the workpiece W is fixed to the facing surface 71as of the machining fluid flow rectifying plate 71a. Another end surface of the columnar shape of the workpiece W is in close contact with the facing surface 71bs of the machining fluid flow rectifying plate 71b.

In a case where the workpiece W is a material for a semiconductor wafer, the shape of the workpiece W is often formed into a columnar shape in advance so that thin plates after cutting become circular thin plates. Here, regarding the workpiece W having a columnar shape, a side surface of the column that forms a curved surface is referred to as an outer peripheral side surface. The workpiece W is disposed in the thin plate machining stabilization unit 70 so that the outer peripheral side surface faces the cutting wire parts 1b. When the workpiece W is sliced by the cutting wire parts 1b, wafers which are thin plates are machined from the workpiece W.

In an electrical discharge cutting step in which the workpiece W is sliced by the cutting wire parts 1b, a portion of the workpiece W where cutting is started by the cutting wire parts 1b is defined as a cutting start portion. In the electrical discharge cutting step in which the workpiece W is sliced by the cutting wire parts 1b, a portion of the workpiece W where the cutting by the cutting wire parts 1b is completed is defined as a machining end portion.

The cutting wire parts 1b are repeatedly wound at predetermined intervals and pass through between the machining fluid flow rectifying plate 71b and the machining fluid flow rectifying plate 71a facing each other in parallel with the workpiece W fixed to the machining fluid flow rectifying plate 71a interposed therebetween.

When the machining fluid flow rectifying plate 71a to which the workpiece W is fixed and the machining fluid flow rectifying plate 71b are installed in an attitude changing mechanism (not illustrated) that changes and fixes attitudes of the machining fluid flow rectifying plate 71a and the machining fluid flow rectifying plate 71b to be relatively rotated or to be relatively inclined to the cutting wire parts 1b, and the machining is performed, a plurality of thin plates can be simultaneously cut out from the workpiece W, the plurality of thin plates each having a cut surface that, when the facing surface 71as of the machining fluid flow rectifying plate 71a is used as a reference surface, forms a specific angle with respect to the reference surface. As a mechanism for rotating or inclining the workpiece W, a rotary stage and a gonio stage can be used.

As illustrated in FIG. 3, the workpiece power feed assistance portion 73 is in contact with the outer peripheral side surface of the workpiece W, and is fixed to the machining fluid flow rectifying plate 71a, at a machining end portion of the workpiece W. In a region of the workpiece W from a diameter portion to the cutting start portion, the workpiece retaining unit 72 is in contact with the outer peripheral side surface of the workpiece W, and is fixed to the machining fluid flow rectifying plate 71a. In FIG. 3, the workpiece retaining unit 72 is installed along the cut outer peripheral side surface of the workpiece W.

The diameter portion is a portion of the workpiece W where a maximum cutting length is obtained, the workpiece W having a columnar shape and a cutting length of which varying correspondingly to a cutting position of the workpiece W in the z-axis direction. The cutting length is, in the cutting of the workpiece W, the length of cutting by the cutting wire parts 1b during cutting in the horizontal direction, that is, the y-axis direction.

The workpiece power feed assistance portion 73 comes into contact with the outer peripheral side surface of the workpiece W from below the workpiece W to hold and fix the workpiece W. In addition, the workpiece power feed assistance portion 73 constitutes a power supply path from the machining fluid flow rectifying plate 71a to the workpiece W. The workpiece power feed assistance portion 73 is fixed to the machining fluid flow rectifying plate 71a, with the outer peripheral side surface of the workpiece power feed assistance portion 73 in contact with the outer peripheral side surface of a lowermost portion of the workpiece W. That is, the workpiece power feed assistance portion 73 is in contact with the outer peripheral side surface of the machining end portion which is a portion where the cutting of the workpiece W by the cutting wire parts 1b is completed, and is fixed to the machining fluid flow rectifying plate 71a.

The workpiece power feed assistance portion 73 has a columnar shape, for example. Regarding the workpiece power feed assistance portion 73 having a columnar shape, with an axial direction of the columnar shape perpendicular to the facing surface 71as of the machining fluid flow rectifying plate 71a, one end surface of the columnar shape is fixed to the facing surface 71as of the machining fluid flow rectifying plate 71a. The height of the workpiece power feed assistance portion 73 from the facing surface 71as which is an installation surface thereof on the machining fluid flow rectifying plate 71a is set to be less than or equal to the thickness of the workpiece W. The thickness of the workpiece W is the length of the workpiece W in the axial direction of the columnar shape. The shape of the workpiece power feed assistance portion 73 is not limited to the columnar shape.

Such a workpiece power feed assistance portion 73 can be called a lower workpiece holding portion having conductivity that comes into contact with the workpiece W from below to hold the workpiece W.

The thin plate side surface holding portions 75a and 75b come into contact with the outer peripheral side surface of the workpiece W from below the workpiece W to hold and fix the workpiece W. In addition, the thin plate side surface holding portions 75a and 75b constitute a power supply path from the machining fluid flow rectifying plate 71a to the workpiece W. The thin plate side surface holding portions 75a and 75b are disposed on the facing surface 71as of the machining fluid flow rectifying plate 71a at positions below the diameter portion of the workpiece W having a columnar shape, the positions being symmetrical with respect to the workpiece power feed assistance portion 73, and being above the position where cutting of the workpiece W is completed and in contact with the outer peripheral side surface of the workpiece W.

The thin plate side surface holding portions 75a and 75b each have a columnar shape, for example. Regarding the thin plate side surface holding portions 75a and 75b each having a columnar shape, with an axial direction of each columnar shape perpendicular to the facing surface 71as of the machining fluid flow rectifying plate 71a, one end surface of the columnar shape is fixed to the facing surface 71as of the machining fluid flow rectifying plate 71a. The height of the thin plate side surface holding portions 75a and 75b from the facing surface 71as which is the installation surface thereof on the machining fluid flow rectifying plate 71a is set to be less than or equal to the thickness of the workpiece W. The thickness of the workpiece W is the length of the workpiece W in the axial direction of the columnar shape. The shape of the thin plate side surface holding portions 75a and 75b is not limited to the columnar shape.

Such thin plate side surface holding portions 75a and 75b can be each called a lower workpiece holding portion having conductivity that comes into contact with the workpiece W from below to hold the workpiece W. The thin plate side surface holding portions 75a and 75b are cut together with the workpiece W as described later, and a plurality of thin plate portions of the thin plate side surface holding portions 75a and 75b formed by cutting the thin plate side surface holding portions 75a and 75b support and fix the plurality of thin plates formed by being cut from the workpiece W simultaneously with the thin plate portions and separated from each other.

The workpiece retaining unit 72 retains the plurality of thin plates under cutting process from an outer peripheral side surface side on a cutting start portion side of the plurality of thin plates, and collectively fixes the plurality of thin plates under cutting process. By collectively fixing the plurality of thin plates under cutting process, the workpiece retaining unit 72 can reduce shaking of the plurality of thin plates due to vibration of the workpiece W generated by fluid pressure of the machining fluid flow received by cut surfaces of the plurality of thin plates. The workpiece retaining unit 72 has a rectangular parallelepiped shape in which a groove portion 72a is formed which accommodates a part of the workpiece W on the cutting start portion side. The shape of the workpiece retaining unit 72 is not limited to the rectangular parallelepiped shape.

The workpiece retaining unit 72 is not installed at a time when the electrical discharge cutting of the workpiece W is started. Regarding the workpiece retaining unit 72, at a time when the electrical discharge cutting proceeds after the start of the electrical discharge cutting of the workpiece W and the electrical discharge cutting by the cutting wire parts 1b proceeds to a position corresponding to about ⅙ or more and ⅕ or less of a cutting distance of the workpiece W, a contact portion of the workpiece retaining unit 72 is pressed, from above the workpiece W and the plurality of thin plates in the middle of machining, against upper portions of the workpiece W and each thin plate. The workpiece retaining unit 72 is inserted into a space sandwiched between the pair of machining fluid flow rectifying plates 71a and 71b from above the workpiece W and each thin plate. The workpiece retaining unit 72 is automatically disposed by the workpiece retaining unit holding device 78 on the upper portions of the plurality of thin plates under cutting process.

The cutting distance is a distance from the cutting start portion to the machining end portion of the workpiece W, and corresponds to the diameter of the workpiece W.

The workpiece retaining unit holding device 78 automatically disposes the workpiece retaining unit 72 on the upper portions of the plurality of thin plates under cutting process at a predetermined timing in accordance with the control of the control unit 300. In addition, the workpiece retaining unit holding device 78 retracts the workpiece retaining unit 72 from the upper portions of the plurality of thin plates after cutting at a timing when the cutting of the workpiece W is completed in accordance with the control of the control unit 300. The position of the workpiece retaining unit 72 in the height direction is maintained by the workpiece retaining unit holding device 78. The workpiece retaining unit 72 is held at an initial cutting position separated upward from the workpiece W and the cutting wire parts 1b at the start of the cutting. After the start of the cutting, the workpiece retaining unit 72 fixes thin plates being machined into a thin plate shape from the workpiece W. A force for pressing the workpiece retaining unit 72 against the thin plates is obtained by using a driving device such as a motor or an air cylinder, or a weight.

The contact portion of the workpiece retaining unit 72 is a portion where the workpiece retaining unit 72 contacts the upper portion of the workpiece W, that is, the upper portions of the plurality of thin plates. The contact portion of the workpiece retaining unit 72 is formed into a shape following the outer peripheral side surface of the workpiece W, that is, into a shape following the outer peripheral side surfaces of the plurality of thin plates. That is, in a case where the shape of the workpiece W is a columnar shape, the contact portion of the workpiece retaining unit 72 is formed into an arc shape which is a shape following the outer peripheral side surface of the columnar shape.

In addition, a thin plate portion retainer 76 is attached to the contact portion of the workpiece retaining unit 72. The thin plate portion retainer 76 retains the workpiece W from above to collectively fix the plurality of thin plates under cutting process. That is, the thin plate portion retainer 76 retains the plurality of thin plates under cutting process from the outer peripheral side surface side on the cutting start portion side of the plurality of thin plates, and collectively fixes the plurality of thin plates under cutting process. The thin plate portion retainer 76 increases a contact area between the contact portion of the workpiece retaining unit 72 and the workpiece W, that is, a contact area between the contact portion of the workpiece retaining unit 72 and the outer peripheral side surfaces of the plurality of thin plates, and collectively fixes the plurality of thin plates under cutting process. By collectively fixing the plurality of thin plates under cutting process, the thin plate portion retainer 76 increases the contact area between the contact portion of the workpiece retaining unit 72 and the outer peripheral side surfaces of the plurality of thin plates, and reduces shaking of the plurality of thin plates due to vibration of the workpiece W generated by fluid pressure of the machining fluid flow received by the cut surfaces of the plurality of thin plates.

When the workpiece retaining unit 72 is pressed against the outer peripheral side surface of the workpiece W, that is, the outer peripheral side surfaces of the plurality of thin plates, the thin plate portion retainer 76 is deformed between the contact portion of the workpiece retaining unit 72 and the outer peripheral side surface of the workpiece W. A part of the deformed thin plate portion retainer 76 enters inside a plurality of machined grooves formed between the plurality of thin plates. Consequently, in the wire electrical discharge machining apparatus 1000, the deformed thin plate portion retainer 76 maintains intervals between the plurality of thin plates being cut out from the workpiece W, which decreases a risk that the thin plates under cutting process are shaken by the machining fluid and cracked.

In addition, another part of the deformed thin plate portion retainer 76 does not enter inside the machined grooves, but fills unevenness of the contact portion of the workpiece retaining unit 72 and unevenness of the outer peripheral side surface of each thin plate, and is sandwiched between the contact portion of the workpiece retaining unit 72 and the outer peripheral side surface of each thin plate. Consequently, in the wire electrical discharge machining apparatus 1000, the contact area between the contact portion of the workpiece retaining unit 72 and the outer peripheral side surface of each thin plate via the thin plate portion retainer 76 is enlarged, which enhances the force for holding, from above the workpiece W, the outer peripheral side surfaces of the plurality of thin plates under cutting process to be cut out from the workpiece W.

Therefore, the thin plate portion retainer 76 is deformed when the workpiece retaining unit 72 is pressed against the outer peripheral side surface of the workpiece W, that is, the outer peripheral side surfaces of the plurality of thin plates, holds the plurality of thin plates under cutting process from the thickness direction of the thin plates, and holds the outer peripheral side surfaces of the plurality of thin plates under cutting process from above the workpiece W, thereby reducing shaking and cracking, caused by the machining fluid, of the thin plates under cutting process.

For fixing the workpiece W to the machining fluid flow rectifying plate 71a, a conductive adhesive, a conductive sheet, a conductive adhesive tape, a low melting point metal, a conductive wax, or the like having conductivity is used. Use of a conductive material for fixing the workpiece W to the machining fluid flow rectifying plate 71a allows conduction between the workpiece W and the machining fluid flow rectifying plate 71a. Consequently, as described later, the electrical discharge machining power can be supplied from the machining power supply 5 to the workpiece W via the machining fluid flow rectifying plate 71a.

In addition to the conductive adhesive, the conductive sheet, the conductive adhesive tape, the low melting point metal, and the conductive wax having conductivity, screw fastening using a metal screw is used for fixing the workpiece power feed assistance portion 73 and the thin plate side surface holding portions 75a and 75b to the machining fluid flow rectifying plate 71a. Use of a conductive material for fixing the workpiece power feed assistance portion 73 and the thin plate side surface holding portions 75a and 75b to the machining fluid flow rectifying plate 71a allows conduction between the machining fluid flow rectifying plate 71a and each of the workpiece power feed assistance portion 73 and the thin plate side surface holding portions 75a and 75b. Consequently, as described later, the electrical discharge machining power can be supplied from the machining power supply 5 to the workpiece W via the machining fluid flow rectifying plate 71a and the workpiece power feed assistance portion 73. In addition, the electrical discharge machining power can be supplied from the machining power supply 5 to the workpiece W via the machining fluid flow rectifying plate 71a and the thin plate side surface holding portions 75a and 75b.

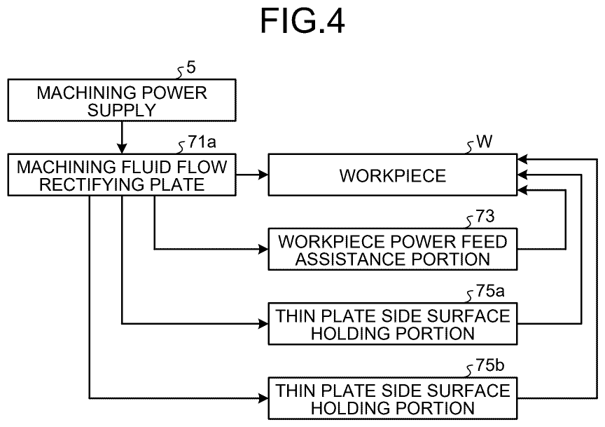

FIG. 4 is a diagram illustrating an electrical discharge machining power supply path from the machining power supply 5 to the workpiece W in the wire electrical discharge machining apparatus 1000 according to the first embodiment. In the wire electrical discharge machining apparatus 1000, the electrical discharge machining power is supplied from the machining power supply 5 to the workpiece W via the machining fluid flow rectifying plate 71a. The electrical discharge machining power is supplied from the machining power supply 5 to the workpiece W via the machining fluid flow rectifying plate 71a and the workpiece power feed assistance portion 73, as well. The electrical discharge machining power is supplied from the machining power supply 5 to the workpiece W via the machining fluid flow rectifying plate 71a and the thin plate side surface holding portion 75a, as well. The electrical discharge machining power is supplied from the machining power supply 5 to the workpiece W via the machining fluid flow rectifying plate 71a and the thin plate side surface holding portion 75b, as well.

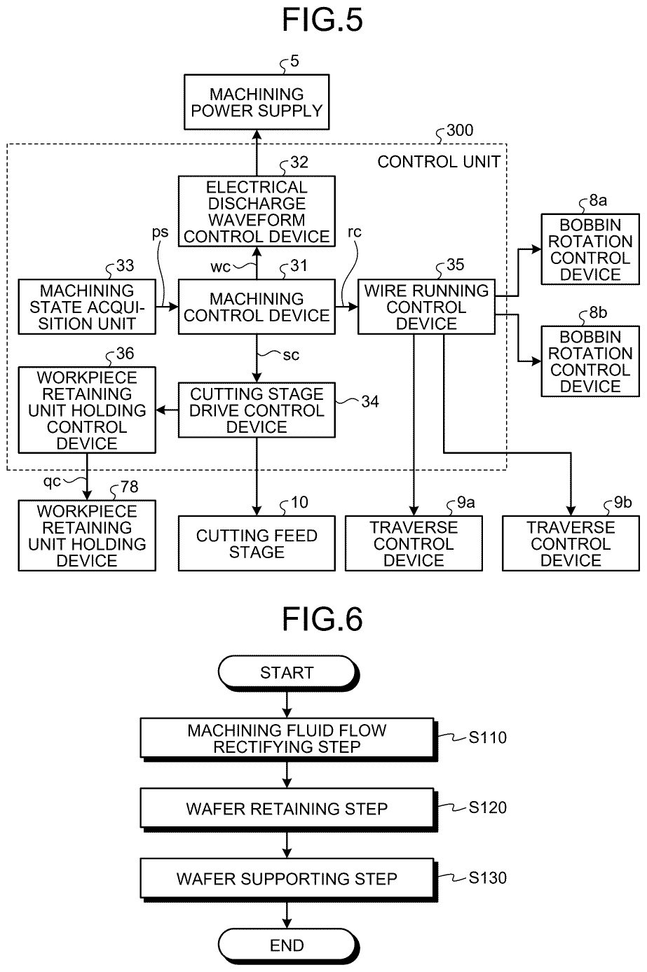

The control unit 300 controls the entirety of the wire electrical discharge machining apparatus 1000. FIG. 5 is a block diagram illustrating an exemplary configuration of the control unit 300 included in the wire electrical discharge machining apparatus 1000 according to the first embodiment. The control unit 300 includes a machining control device 31, an electrical discharge waveform control device 32, a machining state acquisition unit 33, a cutting stage drive control device 34, a wire running control device 35, and a workpiece retaining unit holding control device 36. The control unit 300 controls the wire electrical discharge machining apparatus 1000.

The machining state acquisition unit 33 acquires various types of machining state information ps including the position of the workpiece W in the z-axis direction from outputs of various sensors, and outputs the acquired machining state information ps to the machining control device 31. The machining control device 31 controls the electrical discharge waveform control device 32, the cutting stage drive control device 34, and the wire running control device 35 on the basis of the acquired machining state information ps. The electrical discharge waveform control device 32 controls the machining power supply 5 on the basis of an electrical discharge waveform command wc input from the machining control device 31, and controls a waveform of a voltage applied to between electrodes or a waveform of a current flowing between the electrodes.

The wire running control device 35 drives and controls the bobbin rotation control devices 8a and 8b on the basis of a wire electrode running command rc input from the machining control device 31, and controls the running of the wire electrode 1. In addition, the wire running control device 35 drives and controls the traverse control devices 9a and 9b on the basis of the wire electrode running command rc input from the machining control device 31, and controls traverse control.

The cutting stage drive control device 34 drives the cutting feed stage 10 on the basis of a stage command sc input from the machining control device 31, and controls the relative positions of the workpiece W and the cutting wire parts 1b. In addition, the cutting stage drive control device 34 sends the stage command sc also to the workpiece retaining unit holding control device 36 connected to the workpiece retaining unit holding device 78.

The workpiece retaining unit holding control device 36 monitors a coordinate value of the cutting feed stage 10 in the z-axis direction on the basis of the stage command sc from the cutting stage drive control device 34, drives and controls the workpiece retaining unit holding device 78 based on a retainer holding control command qc at the same time as the cutting feed stage 10 reaches a preset first position, and controls the disposition of the workpiece retaining unit 72 onto upper portions of the plurality of thin plates under cutting process. In addition, the workpiece retaining unit holding control device 36 monitors the coordinate value of the cutting feed stage 10 in the z-axis direction on the basis of the stage command sc from the cutting stage drive control device 34, drives and controls the workpiece retaining unit holding device 78 based on the retainer holding control command qc at the same time as the cutting feed stage 10 reaches a preset second position, and performs control to retract the workpiece retaining unit 72 from the upper portions of the plurality of thin plates after cutting.

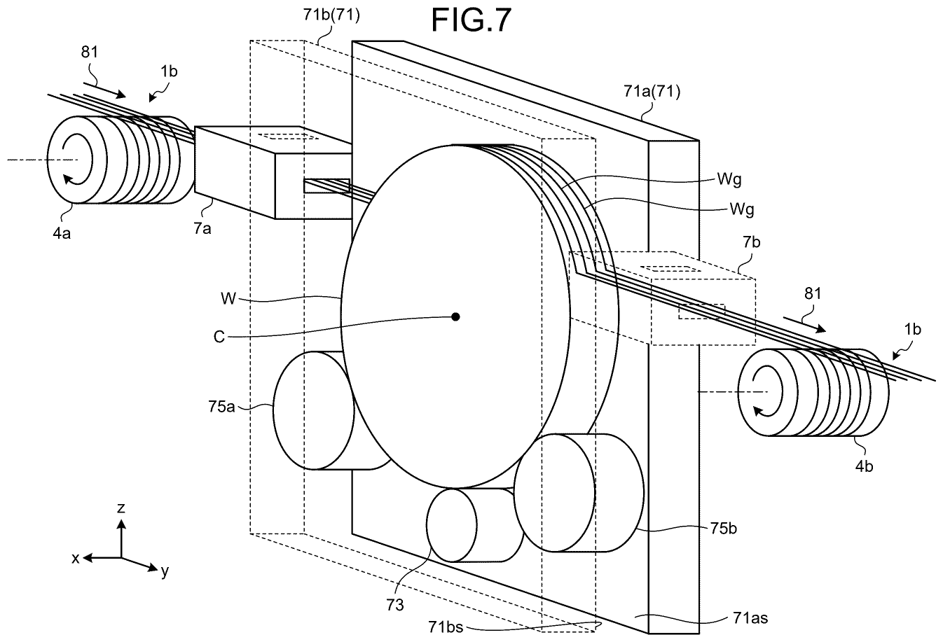

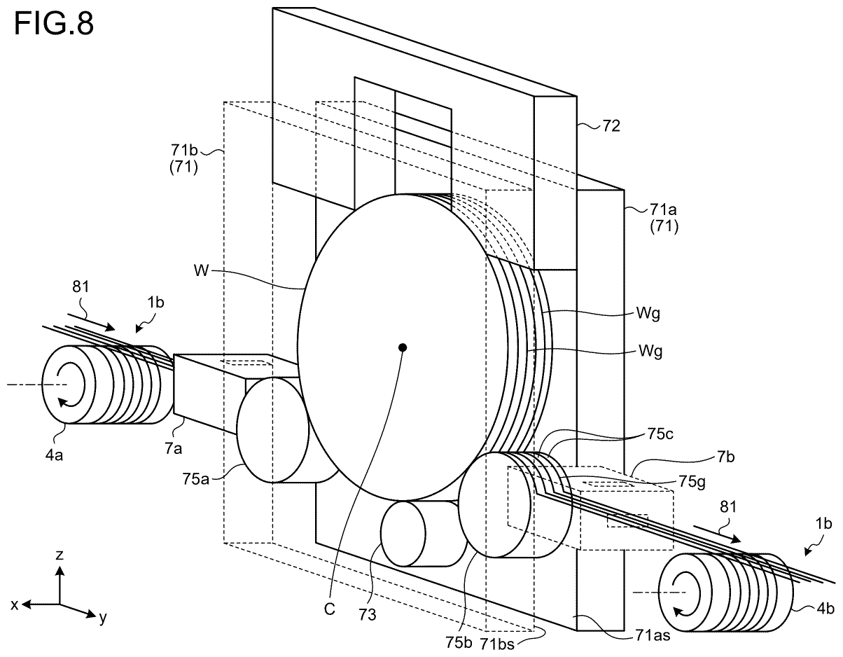

FIG. 6 is a flowchart illustrating an operation of the wire electrical discharge machining apparatus 1000 according to the first embodiment during cutting. FIG. 7 is a first perspective view illustrating a state of thin plates during cutting in the thin plate machining stabilization unit 70 included in the wire electrical discharge machining apparatus 1000 according to the first embodiment. FIG. 8 is a second perspective view illustrating the state of the thin plates during the cutting in the thin plate machining stabilization unit 70 included in the wire electrical discharge machining apparatus 1000 according to the first embodiment.

FIG. 7 illustrates a state where the workpiece W is cut to a position corresponding to about ⅙ from the outer peripheral side surface of the workpiece W on the cutting start portion side, that is, from the outer peripheral side surface of the workpiece W on the upper side thereof in the height direction. FIG. 8 illustrates a state where the cutting further proceeds from the state illustrated in FIG. 7, the workpiece retaining unit 72 is in contact with the outer peripheral side surface of the workpiece W on the cutting start portion side, that is, the outer peripheral side surfaces of the plurality of thin plates on the upper side thereof, and the plurality of thin plates under cutting process are held by the workpiece retaining unit 72. In addition, FIG. 8 illustrates a state where the cutting wire parts 1b exceed a central axis C of the workpiece W in a downward direction in the z-axis direction, and the thin plate side surface holding portions 75a and 75b fixed in contact with the outer peripheral side surface of the workpiece W are also cut simultaneously with the workpiece W by the cutting wire parts 1b. In addition, for easy understanding, FIG. 7 illustrates a through-view of seeing state through some components of the wire electrical discharge machining apparatus 1000. Hereinafter, the operation of the wire electrical discharge machining apparatus 1000 during cutting will be described. Note that the following operation is performed under the control of the control unit 300.

At the start of the cutting, the workpiece W is installed and fixed in the thin plate machining stabilization unit 70. At the start of the cutting, the workpiece W is separated from the cutting wire parts 1b and is located just below the cutting wire parts 1b. In addition, at the start of the cutting, the workpiece retaining unit 72 is not installed. In that state, the cutting wire parts 1b start running. The cutting wire parts 1b run through the plurality of machining fluid ejection holes 7c of the nozzles 7a and 7b, and run through just above the workpiece W sandwiched between the machining fluid flow rectifying plate 71a and the machining fluid flow rectifying plate 71b.

The electrical discharge machining power is supplied from the machining power supply 5 to the workpiece W via the machining fluid flow rectifying plate 71a. The electrical discharge machining power supply from the machining power supply 5 to the workpiece W is performed from the machining fluid flow rectifying plate 71a via each of the workpiece power feed assistance portion 73, the thin plate side surface holding portion 75a and the thin plate side surface holding portion 75b. The electrical discharge machining power is supplied from the machining power supply 5 to the cutting wire parts 1b via the power feed contact units 6a and 6b. The machining fluid is supplied from the nozzles 7a and 7b to a gap between the machining fluid flow rectifying plate 71a and the machining fluid flow rectifying plate 71b.

When the cutting is started, the control unit 300 raises the cutting feed stage 10 to change the relative positions of the workpiece W and the cutting wire parts 1b. Specifically, the control unit 300 raises the cutting feed stage 10, thereby moving upward the thin plate machining stabilization unit 70 in which the workpiece W is installed and fixed. Consequently, the workpiece W installed in the thin plate machining stabilization unit 70 relatively approaches and comes into contact with the cutting wire parts 1b, and is cut by the cutting wire parts 1b.

When the cutting is started, a machining fluid flow rectifying step is performed in step S110. In the machining fluid flow rectifying step, the flow of the machining fluid supplied from the nozzles 7a and 7b to the thin plate machining stabilization unit 70 is rectified so that the machining fluid collides with the workpiece W. In the thin plate machining stabilization unit 70, regarding the machining fluid supplied from the nozzles 7a and 7b to the thin plate machining stabilization unit 70, the flow thereof in the x-axis direction is restricted by the machining fluid flow rectifying plate 71a and the machining fluid flow rectifying plate 71b, and the machining fluid collides with the workpiece W. That is, the facing surface 71as of the machining fluid flow rectifying plate 71a and the facing surface 71bs of the machining fluid flow rectifying plate 71b regulate movement of the flow of the machining fluid supplied to the gap between the machining fluid flow rectifying plate 71a and the machining fluid flow rectifying plate 71b in the x-axis direction which is the central axis direction of the workpiece W, and form a flow path that guides the flow of the machining fluid to the workpiece W.

Therefore, it can be said that the machining fluid flow rectifying step is a step of ejecting the machining fluid from the nozzles 7a and 7b toward the space sandwiched between the pair of machining fluid flow rectifying plates 71, guiding the flow of the machining fluid to the workpiece W by the facing surfaces 7las and 71bs of the pair of machining fluid flow rectifying plates 71, and supplying the machining fluid to the gap between the plurality of cutting wire parts 1b and the workpiece W.

As described above, the control unit 300 controls each component of the wire electrical discharge machining apparatus 1000, so that electrical discharge cutting of the workpiece W proceeds. Note that the machining fluid flow rectifying step in step S110 is continuously performed from the start of the cutting to the end of the cutting.

Thereafter, in step S120, a wafer retaining step is performed. In the wafer retaining step, at a time when the electrical discharge cutting proceeds and the electrical discharge cutting by the cutting wire parts 1b proceeds to a position corresponding to about ⅙ or more and ⅕ or less of the cutting distance of the workpiece W, from above the workpiece W and the plurality of thin plates under cutting process, the contact portion of the workpiece retaining unit 72 is pressed against upper portions of the workpiece W and each thin plate.

Consequently, the thin plate portion retainer 76 attached to the contact portion of the workpiece retaining unit 72 retains the workpiece W from above to collectively fix the plurality of thin plates under cutting process. That is, the thin plate portion retainer 76 retains the plurality of thin plates under cutting process from the outer peripheral side surface side on the cutting start portion side of the plurality of thin plates, and collectively fixes the plurality of thin plates under cutting process. By collectively fixing the plurality of thin plates under cutting process, the thin plate portion retainer 76 reduces shaking of the plurality of thin plates due to vibration of the workpiece W generated by fluid pressure of the machining fluid flow received by the cut surfaces of the plurality of thin plates.

Then, the electrical discharge cutting of the workpiece W proceeds in a state where the plurality of thin plates under cutting process are collectively fixed by the workpiece retaining unit 72 as described above. Here, since the plurality of thin plates to be cut out from the workpiece W are held by the thin plate side surface holding portions 75a and 75b in contact with the outer peripheral side surfaces of the plurality of thin plates, the plurality of thin plates are not shaken or deflected by the pressure of the machining fluid supplied from the nozzles 7a and 7b toward the machined grooves Wg being formed, and a change in the gap between adjacent thin plates in the x-axis direction is reduced. As a result, the supply of the machining fluid to the inside of the machined grooves formed between the adjacent thin plates does not change, the machining debris generated by the electrical discharge cutting is stably evacuated from between the electrodes, i.e., the gap between the workpiece W and the cutting wire parts 1b, and the cutting wire parts 1b are stably cooled. Consequently, the wire electrical discharge machining apparatus 1000 can stably continue the wire electrical discharge cutting of the workpiece W.

Therefore, it can be said that the wafer retaining step is a step of holding the workpiece W to be divided during the cutting process from above the workpiece W and the plurality of cutting wire parts 1b.

Thereafter, in step S130, a wafer supporting step is performed. When the electrical discharge cutting further proceeds and the cutting wire parts 1b reach the thin plate side surface holding portions 75a and 75b in the z-axis direction, as illustrated in FIG. 8, the thin plate side surface holding portions 75a and 75b are subjected to the electrical discharge cutting from above by the cutting wire parts 1b simultaneously together with the workpiece W.

In the wafer supporting step, the workpiece power feed assistance portion 73 and the thin plate side surface holding portions 75a and 75b which are lower workpiece holding portions having conductivity come into contact with the workpiece W from below to hold the workpiece W during the cutting of the workpiece W, the lower workpiece holding portions being provided over upper and lower regions of the machining end portion which is the portion where the cutting of the workpiece W is completed in a cutting direction of the workpiece W, and fixed to the facing surface 71as of the machining fluid flow rectifying plate 71a which is one of the pair of machining fluid flow rectifying plates 71. In that state, power is supplied from the machining fluid flow rectifying plate 71a to the workpiece W via the workpiece power feed assistance portion 73 and the thin plate side surface holding portions 75a and 75b which are lower workpiece holding portions, from the start of the cutting of the workpiece W to the end of the cutting of the workpiece W.

When the electrical discharge cutting proceeds and the cutting wire parts 1b reach the thin plate side surface holding portions 75a and 75b in the z-axis direction, as illustrated in FIG. 8, the thin plate side surface holding portions 75a and 75b are subjected to the electrical discharge cutting from above by the cutting wire parts 1b simultaneously with the workpiece W. Also in that state, to the end of the cutting of the workpiece W, power is supplied from the machining fluid flow rectifying plate 71a to the workpiece W via the workpiece power feed assistance portion 73 and the thin plate side surface holding portions 75a and 75b which are lower workpiece holding portions.

The thin plate side surface holding portions 75a and 75b are installed so that a lowermost portion of each thereof is located below the lowermost portion of the workpiece W. Therefore, a holding force of each of the thin plate side surface holding portions 75a and 75b with respect to the plurality of thin plates to be machined from the workpiece W is not lost due to the thin plate side surface holding portions 75a and 75b being cut and separated into the plurality of thin plates in the middle of machining of the workpiece W. That is, at a time when the electrical discharge cutting performed on the workpiece W is completed, a plurality of thin plate portions 75c are formed in the thin plate side surface holding portions 75a and 75b, each of the thin plate portions 75c having a width equivalent to that of a thin plate formed from the workpiece W, and the number of thin plate portions 75c being the same as that of thin plates formed from the workpiece W.

However, the plurality of thin plate portions 75c formed in the thin plate side surface holding portions 75a and 75b are not separated from the workpiece W. Therefore, in a state where the electrical discharge cutting of the plurality of thin plates from the workpiece W is completed, a holding state of the plurality of thin plates machined from the workpiece W is continued by each of the thin plate portions 75c formed at the thin plate side surface holding portions 75a and 75b and the workpiece retaining unit 72.

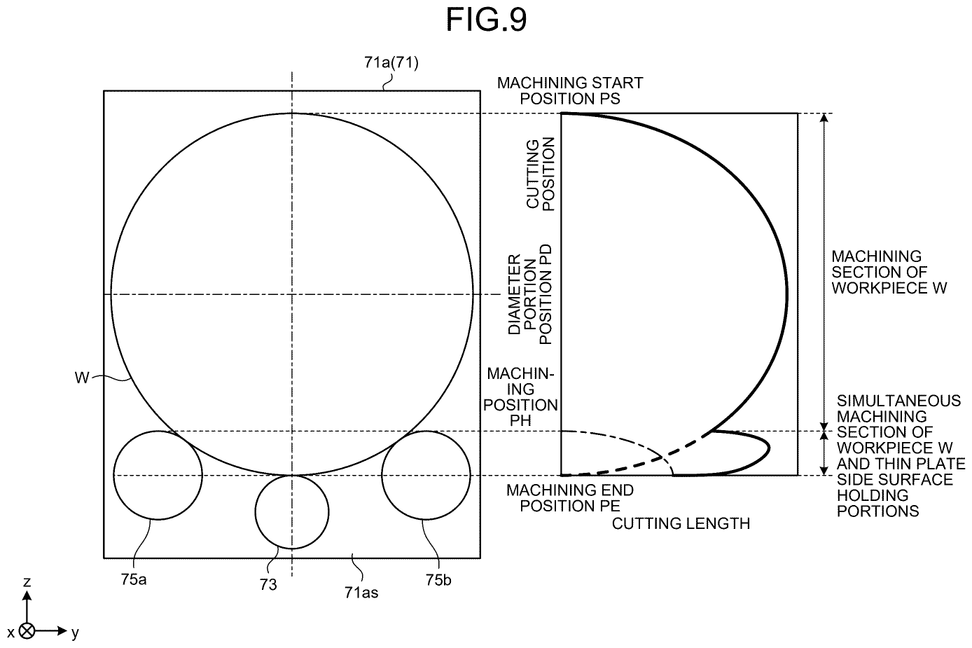

FIG. 9 is a set of diagrams for explaining a relationship between cutting position and cutting length of the workpiece W during cutting by the wire electrical discharge machining apparatus 1000 according to the first embodiment. The left diagram of FIG. 9 illustrates an example of a positional relationship among the workpiece W, the workpiece power feed assistance portion 73, and the thin plate side surface holding portions 75a and 75b in an in-plane direction of the facing surface 71as of the machining fluid flow rectifying plate 71a. The right diagram of FIG. 9 illustrates a cutting length corresponding to a cutting position of the workpiece W in the left diagram of FIG. 9. A solid line in the right diagram of FIG. 9 indicates a cutting length in the cutting of the workpiece W by the wire electrical discharge machining apparatus 1000. A broken line in the right diagram of FIG. 9 indicates a cutting length in the cutting of the workpiece W in a case where the thin plate side surface holding portions 75a and 75b are not installed in the configuration of the wire electrical discharge machining apparatus 1000. A dashed-dotted line in the right diagram of FIG. 9 indicates a cutting length in a case where only the thin plate side surface holding portions 75a and 75b are cut by the wire electrical discharge machining apparatus 1000.

In cutting of the workpiece W having a columnar shape by the wire electrical discharge machining apparatus 1000, the cutting length varies correspondingly to the cutting position in the height direction during the cutting, that is, correspondingly to the cutting position in the z-axis direction during the cutting.

As indicated by the solid line in the right diagram of FIG. 9, when the cutting proceeds from an uppermost end portion of the workpiece W which is a machining start position PS of the workpiece W toward a lowermost end portion of the workpiece W which is a machining end position PE of the workpiece W, in a machining section of the workpiece W, the cutting length varies correspondingly to the cutting position of the workpiece W in the height direction, and the cutting length is at a maximum at a diameter portion position PD of the workpiece W. When the cutting is further continued and the cutting wire parts 1b pass through the diameter portion position PD of the workpiece W in the height direction, then the cutting length decreases as the cutting proceeds.

When the cutting further proceeds and the cutting wire parts 1b reach the thin plate side surface holding portions 75a and 75b in the z-axis direction at a machining position PH, the thin plate side surface holding portions 75a and 75b are subjected to the cutting from above by the cutting wire parts 1b simultaneously with the workpiece W. From this time point, the cutting length becomes a total cutting length of the cutting length of the workpiece W and the cutting lengths of the thin plate side surface holding portions 75a and 75b, which temporarily increases with the proceeding of the cutting, and then decreases. That is, in the wire electrical discharge machining apparatus 1000, the thin plate side surface holding portions 75a and 75b are cut together with the workpiece W, so that a rapid decrease in the cutting length in the vicinity of the machining end portion is alleviated.

As indicated by the broken line in the right diagram of FIG. 9, in the case where the thin plate side surface holding portions 75a and 75b are not disposed in the configuration of the wire electrical discharge machining apparatus 1000, the cutting length decreases correspondingly to a change in the cutting position when the cutting proceeds beyond the machining position PH, and rapidly decreases in the vicinity of the machining end portion. The rapid decrease in the cutting length becomes one of causes of a sudden change in a wire electrical discharge machining state. When the wire electrical discharge machining state suddenly changes, the risk of wire breakage increases. In addition, when the wire electrical discharge machining state suddenly changes, and if an appropriate machining condition for the thin plates is not selected for the change in the cutting length, there occurs variation in the thickness of machined thin plates in cut surface planes, which adversely affects the quality of the thin plates.

On the other hand, in the wire electrical discharge machining apparatus 1000, the thin plate side surface holding portions 75a and 75b disposed for holding the plurality of thin plates are cut together with the workpiece W, and thereby the rapid decrease in the cutting length in the vicinity of the machining end portion is alleviated, and it is possible to reduce occurrence of the adverse effect on the cutting quality of the thin plates due to the sudden change in the electrical discharge machining state described above. In addition, in the wire electrical discharge machining apparatus 1000, the thin plate side surface holding portions 75a and 75b are provided and thus a situation is alleviated in which the machining fluid flow supplied from the nozzles 7a and 7b directly hits the thin plates, so that shaking of the thin plates by the machining fluid flow is reduced, and cracking of the thin plates or chipping of the thin plates which is likely to occur at the machining end portion of the thin plate is prevented from occurring.

Next, disposition positions of the thin plate side surface holding portions 75a and 75b with respect to the workpiece W and the size of the thin plate side surface holding portions 75a and 75b will be described. The thin plate side surface holding portions 75a and 75b are fixed to the machining fluid flow rectifying plate 71a in a state where the outer peripheral side surfaces of the thin plate side surface holding portions 75a and 75b are in contact with the outer peripheral side surface of the workpiece W. Contact positions of the outer peripheral side surfaces of the thin plate side surface holding portions 75a and 75b with respect to the outer peripheral side surface of the workpiece W are each located in a section in which an uncut length in the cutting direction of the workpiece W is ½ or less of the entire cutting length of the workpiece W in the height direction, that is, in the cutting direction of the workpiece W, the section also being located above a position where the outer peripheral side surface of the workpiece power feed assistance portion 73 is in contact with the outer peripheral side surface of the workpiece W, that is, the section also being located above a position where the cutting of the workpiece W is completed.

The uncut length in the cutting direction is the length of a region where the workpiece W is not yet cut in the cutting direction which is a downward direction, that is, a downward z-axis direction. The cutting length of the entire workpiece W is the length of the diameter of the workpiece W having a columnar shape.

The width of the thin plate side surface holding portions 75a and 75b is set to a length with which the outer peripheral side surfaces of the thin plate side surface holding portions 75a and 75b in contact with the outer peripheral side surface of the workpiece W do not protrude from the machining fluid flow rectifying plates 71a and 71b. The width of the thin plate side surface holding portions 75a and 75b is a maximum length of the thin plate side surface holding portions 75a and 75b in the y-axis direction, that is, the maximum length of the thin plate side surface holding portions 75a and 75b in the running direction of the cutting wire parts 1b with respect to the workpiece W. In a state where the workpiece W has been completely cut and the cutting wire parts 1b have passed through the entire of the workpiece W, there is a remaining machining portion in each of the thin plate side surface holding portions 75a and 75b.

As described above, the thin plate side surface holding portions 75a and 75b are constituted with a conductive material in order to realize a power supply function to the workpiece W. On the other hand, even with such a conductive material, for example, in a case where there is a significant difference in a physical property value such as an electric resistance value or thermal conductivity between the conductive material and a material of the workpiece W, there arises a difference in electrical discharge machining characteristics, such as a difference in a machining speed due to a difference in likelihood of occurrence of arc discharge, or a difference in the degree of damage of the wire electrode 1 due to a difference in wearing characteristics of the wire electrode 1. As a result, it can be assumed that in a region where the workpiece W and the thin plate side surface holding portions 75a and 75b are simultaneously cut, the influence of the difference in the electrical discharge machining characteristics on the cutting becomes significant, which destabilizes the electrical discharge machining.

Therefore, the material for the thin plate side surface holding portions 75a and 75b is preferably the same conductive material as that for the workpiece W, with which the same electrical discharge machining characteristics as those of the workpiece W are obtained. For example, in a case where the workpiece W made of SiC is cut, the thin plate side surface holding portions 75a and 75b manufactured by machining a sintered body made of Sic powder can be used.

When the cutting of the workpiece W having a columnar shape reaches the vicinity of the machining end portion of the workpiece W and a state approaches where the plurality of thin plates are cut and separated from the workpiece W, the flow rate of the machining fluid supplied from the nozzles 7a and 7b is adjusted to a flow rate that does not cause breakage of portions of the wire electrode 1 corresponding to the cutting wire parts 1b. Consequently, an external force that shakes the plurality of thin plates under cutting process, that is, the fluid pressure of the machining fluid flow received by the cut surfaces of the plurality of thin plates is reduced. In that state, the cutting wire parts 1b pass through the workpiece W while continuing the cutting, reach the workpiece power feed assistance portion 73, and start cutting the workpiece power feed assistance portion 73 made of a material similar to that of the workpiece W. Thereafter, when the control unit 300 determines that the cutting into the thin plates is completely completed on the basis of the degree of proceeding of the cutting wire parts 1b in the cutting direction, the cutting is stopped.

When the workpiece W is separated into the plurality of thin plates, an electrical discharge machining power supply path from the machining fluid flow rectifying plate 71a to the workpiece W may be interrupted depending on a state of separation of the thin plates from the workpiece W. The workpiece power feed assistance portion 73 and the thin plate side surface holding portions 75a and 75b constitute, from the start of the cutting to the completion of the cutting, an electrical discharge machining power supply path to the workpiece W and to the plurality of thin plates under cutting process. Consequently, the wire electrical discharge machining apparatus 1000 can stably continue the wire cutting of the workpiece W.

When an electrical discharge machining power supply path to the cutting wire parts 1b is interrupted just before the cutting is completed, the cutting is suspended, which provides a thin plate that is not completely separated due to a remaining machining portion that has not been cut yet, or a thin plate that cracks at a boundary between the remaining machining portion and the cut portion that has already cut. In addition, between the electrodes, which is an electrical discharge machining gap in the cutting direction, machining slightly precedes a tip of each cutting wire part 1b. Therefore, the thin plates are cut and separated before the cutting wire parts 1b completely pass through the workpiece W. As a result, remaining machining portions remain as minute leftover protrusions at the machining end portions of the separated thin plates, which reduces cutting quality and yield of the thin plates.

On the other hand, the workpiece power feed assistance portion 73 is in contact with the workpiece W and is fixed at a position in contact with the lowermost end portion of the workpiece W, and thus can hold the plurality of thin plates together with the workpiece retaining unit 72 and the thin plate side surface holding portions 75a and 75b against the external force that shakes the plurality of thin plates just before being separated, and can prevent the occurrence of cracking and chipping of the thin plates.

The workpiece power feed assistance portion 73 and the thin plate side surface holding portions 75a and 75b constitute, from the start of the cutting to the completion of the cutting, the electrical discharge machining power supply path to the workpiece W and the plurality of thin plates under cutting process. Consequently, the wire electrical discharge machining apparatus 1000 can stably continue the wire cutting of the workpiece W. Therefore, in the wire electrical discharge machining apparatus 1000, the electrical discharge machining power supply path from the machining fluid flow rectifying plate 71a to the workpiece W is not interrupted depending on a state of separation of the thin plates from the workpiece W, and it is possible to prevent the occurrence of a leftover protrusion caused by the cutting wire parts 1b not completely passing through the workpiece W, which is attributable to the interruption of the electrical discharge machining power supply path from the machining fluid flow rectifying plate 71a to the workpiece W.

As described above, the wire electrical discharge machining apparatus 1000 according to the first embodiment realizes: a wire electrical discharge machining apparatus that generates electrical discharge between a plurality of cutting wire parts that are running and a workpiece to perform electrical discharge machining on the workpiece with energy generated by the electrical discharge, and simultaneously cuts a plurality of wafers from the workpiece, the wire electrical discharge machining apparatus including: a wire electrode including the plurality of cutting wire parts spaced apart from each other in parallel and facing the workpiece; a power feed unit that generates electrical discharge between the plurality of cutting wire parts and the workpiece; a pair of machining fluid flow rectifying plates having conductivity connected to a power supply and provided in contact with both sides of the workpiece so as to sandwich the workpiece; a pair of nozzles in which the plurality of cutting wire parts are inserted, the pair of nozzles including a plurality of machining fluid ejection holes that eject a machining fluid toward a space sandwiched between the pair of machining fluid flow rectifying plates to supply the machining fluid to a gap between the plurality of cutting wire parts and the workpiece; a cutting feed stage that moves the pair of machining fluid flow rectifying plates upward and downward relative to the plurality of cutting wire parts; a workpiece retaining unit that holds the workpiece to be divided during cutting from above the workpiece and the plurality of cutting wire parts; and a lower workpiece holding portion having conductivity that comes into contact with the workpiece from below to hold the workpiece.

As described above, the wire electrical discharge machining apparatus 1000 according to the first embodiment has a structure in which the plurality of thin plates to be cut and separated from the workpiece W by cutting process are held, from the outer peripheral surface side of the workpiece W, by the workpiece power feed assistance portion 73, the thin plate side surface holding portions 75a and 75b, and the workpiece retaining unit 72. Consequently, in the wire electrical discharge machining apparatus 1000, it is possible to reduce or prevent shaking of the thin plates by the flow of the machining fluid supplied from the nozzles 7a and 7b, and to prevent occurrence of cracking of the thin plates and chipping of the thin plates which are likely to occur at the machining end portions of the thin plates just before the completion of the cutting, and to prevent occurrence of leftover protrusions at the machining end portions of the thin plates due to incomplete cutting of the machining end portion of the workpiece W at the end of the cutting.

In addition, since the wire electrical discharge machining apparatus 1000 has the above structure, it is not necessary to greatly reduce the flow rate of the machining fluid in order to mitigate the external force on the thin plates due to the collision of the machining fluid flow against the thin plates when the end of the cutting approaches, and the evacuation of the machining debris from between the electrodes and the cooling state of the cutting wire parts 1b near between the electrodes are not deteriorated. Consequently, the wire electrical discharge machining apparatus 1000 can prevent a decrease in a machining speed due to defective evacuation of the machining debris or insufficient cooling of the cutting wire parts 1b, and can prevent a risk of the wire electrode 1 due to a sudden change in the wire electrical discharge machining state caused by a significant reduction in the flow rate of the machining fluid.

Therefore, the wire electrical discharge machining apparatus 1000 according to the first embodiment achieves an effect that it is possible to prevent damage to thin plates when the thin plates are cut.

### Second Embodiment

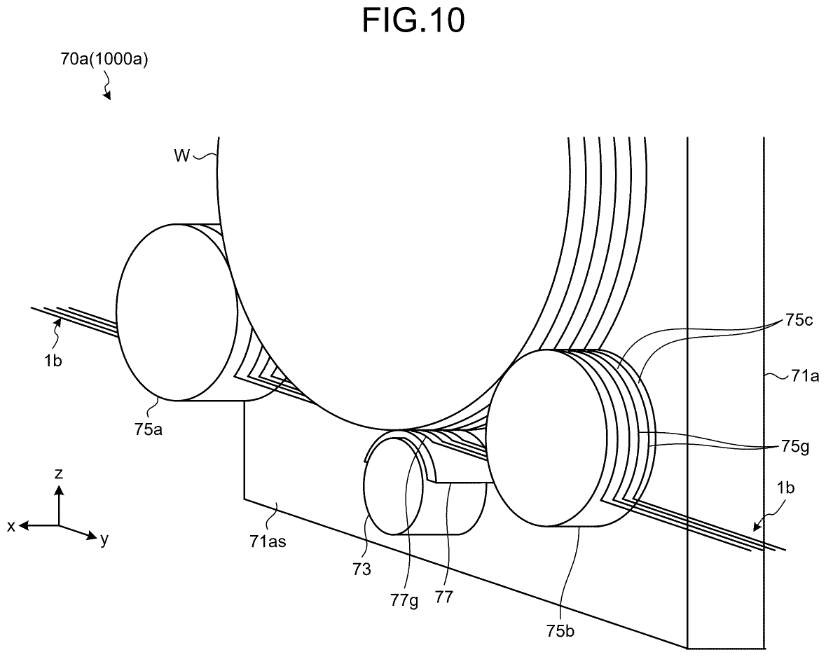

FIG. 10 is a schematic view illustrating an exemplary configuration of the workpiece power feed assistance portion 73 included in a wire electrical discharge machining apparatus 1000a according to a second embodiment. FIG. 10 illustrates a state where, in cutting of the workpiece W into thin plates performed by the wire electrical discharge machining apparatus 1000a, the cutting wire parts 1b pass through the workpiece W and the cutting of the workpiece W into the thin plates is completed, and the workpiece W is separated into the plurality of thin plates. In FIG. 10, a conductive connecting part 77 is provided between the workpiece W and the workpiece power feed assistance portion 73.

The wire electrical discharge machining apparatus 1000a according to the second embodiment includes a thin plate machining stabilization unit 70a instead of the thin plate machining stabilization unit 70, which is a difference from the wire electrical discharge machining apparatus 1000 according to the first embodiment. The thin plate machining stabilization unit 70a includes the conductive connecting part 77, which is a difference from the thin plate machining stabilization unit 70 according to the first embodiment. The rest of the configuration of the wire electrical discharge machining apparatus 1000a according to the second embodiment is similar to that of the wire electrical discharge machining apparatus 1000 according to the first embodiment, and a redundant description will not be repeated.

In the state illustrated in FIG. 10, a plurality of machined grooves 75g are formed by the cutting wire parts 1b also in the thin plate side surface holding portions 75a and 75b. However, the thin plate side surface holding portions 75a and 75b are not separated into a plurality of thin plates. The plurality of thin plates machined from the workpiece W are held by the outer peripheral side surfaces of the thin plate portions 75c formed in the thin plate side surface holding portions 75a and 75b, and the workpiece retaining unit 72. In FIG. 10, the workpiece retaining unit 72 is not illustrated.

As illustrated in FIG. 10, in the wire electrical discharge machining apparatus 1000a, the conductive connecting part 77 is interposed between the workpiece W and the workpiece power feed assistance portion 73. The cutting is continued even after the workpiece W is completely cut, and thereby the conductive connecting part 77 is cut by the cutting wire parts 1b that have passed through the workpiece W, and machined grooves 77g are formed. In the simultaneous cutting of the plurality of thin plates by the cutting wire parts 1b, the control unit 300 determines that the cutting into the thin plates has been completed when the machined grooves 77g are formed in the conductive connecting part 77 by all portions of the wire electrode 1 that constitute the cutting wire parts 1b, and the machining ends as a result.

In a case where the workpiece W is constituted with SiC and the conductive connecting part 77 is constituted with porous metal, there is a clear difference between the SiC and the porous metal in a situation of generation of a discharge pulse or a short circuit pulse generated between electrodes, and an oscillation frequency of the discharge pulse generated between the electrodes or the machining speed. Therefore, the determination whether the cutting into the thin plates has been completed can be made, for example, by detecting a situation of generation of the discharge pulse with which the state of the cutting suddenly changes.

The conductive connecting part 77 has flexibility, is disposed to be sandwiched between the workpiece power feed assistance portion 73 and the workpiece W, and electrically connects the workpiece power feed assistance portion 73 and the workpiece W. The conductive connecting part 77 fills a gap between the workpiece power feed assistance portion 73 and the workpiece W, thereby increasing a contact area between outer peripheral side surfaces of the workpiece power feed assistance portion 73 and the workpiece W facing each other, and improving conductivity between the workpiece power feed assistance portion 73 and the workpiece W.

For the conductive connecting part 77, a conductive material having flexibility and a characteristic of being easily deformable, such as a low melting point metal or a porous metal, is used. Due to the easily deformable characteristic of the conductive connecting part 77, the conductive connecting part 77 pressed against the two outer peripheral side surfaces, i.e., the outer peripheral side surface of the workpiece W and the outer peripheral side surface of the workpiece power feed assistance portion 73 is deformed. Then, the gap between the outer peripheral side surface of the workpiece W and the outer peripheral side surface of the workpiece power feed assistance portion 73 is filled with the deformed conductive connecting part 77. Consequently, in the wire electrical discharge machining apparatus 1000a, the contact area between the outer peripheral side surfaces of the workpiece power feed assistance portion 73 and the workpiece W facing each other can be increased. Then, by increasing the contact area between the outer peripheral side surfaces of the workpiece power feed assistance portion 73 and the workpiece W facing each other, the conductivity between the workpiece power feed assistance portion 73 and the workpiece W is improved.

As the conductive connecting part 77 to be used, it is only required to be made of a conductive material having a Young's modulus of 80 Gpa or less and a specific electrical resistance value of about 10 Ωcm or less, and be deformable enough to fill a minute gap between the workpiece W and the workpiece power feed assistance portion 73 by being pressurized. An example of the dimension of the minute gap is about 100 μm or more and 300 μm or less. As an example, a porous sheet in which metal such as nickel or cobalt is formed in the form of mesh is deformable by bending or deformable in a compression direction due to the flexibility of the porous portion.

Rubber or silicon rubber formed so as to contain powder of a conductive substance such as silver or carbon and having a specific electrical resistance value of 10 Ωcm or less is similarly deformable by bending or deformable in the compression direction.

Regarding an adhesive tape obtained by molding conductive metal foil such as aluminum foil or copper foil, it is difficult to obtain a sufficient amount of deformation by the adhesive tape itself. However, by forming a laminate in which a plurality of sheets of aluminum foil or copper foil are laminated up to, for example, a thickness of about 1 mm, the laminate can be used as the conductive connecting part 77.

A conductive wax kneaded with carbon powder can also be used as the conductive connecting part 77. Since the conductive wax kneaded with the carbon powder has good moldability, when the conductive wax is interposed between contact surfaces of the workpiece W and the workpiece power feed assistance portion 73 and is rubbed against the contact surfaces, a minute gap between the workpiece W and the workpiece power feed assistance portion 73 can be filled. The conductive wax melts at a temperature of about 40° C. or more and 60° C. or less. Therefore, the conductive wax may be used by being poured, in a molten state, into the minute gap between the workpiece W and the workpiece power feed assistance portion 73.

Preferably, the outer peripheral side surface of the workpiece W and the outer peripheral side surface of the workpiece power feed assistance portion 73 are completely in contact with each other. However, in reality, it is difficult to install the workpiece W and the workpiece power feed assistance portion 73 on the machining fluid flow rectifying plate 71 in a state where the outer peripheral side surface of the workpiece power feed assistance portion 73 is completely in contact with the outer peripheral side surface of the workpiece W. That is, in order that the outer peripheral side surface of the workpiece W and the outer peripheral side surface of the workpiece power feed assistance portion 73 come into complete contact with each other, it is necessary that the parallelism between the outer peripheral side surfaces of the workpiece W and the workpiece power feed assistance portion 73 in contact with each other completely coincide with each other, and the workpiece W and the workpiece power feed assistance portion 73 be installed on the machining fluid flow rectifying plate 71a in a state where the workpiece W and the workpiece power feed assistance portion 73 are in close contact with each other at the contact surfaces of the workpiece W and the workpiece power feed assistance portion 73.

Here, what is meant by the expression “the outer peripheral side surface of the workpiece W and the outer peripheral side surface of the workpiece power feed assistance portion 73 come into complete contact with each other” is that the contact surfaces of the outer peripheral side surface of the workpiece W and the outer peripheral side surface of the workpiece power feed assistance portion 73 are continuously in contact with each other without interruption in the y-axis direction, that is, in the axial direction of the workpiece W.

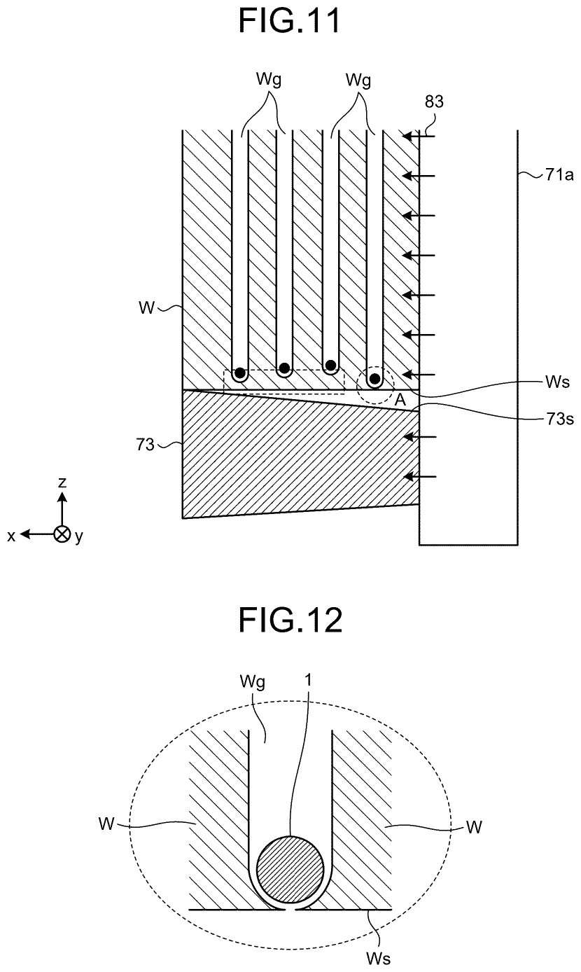

FIG. 11 is a conceptual diagram illustrating an example of a state of the thin plates just before the completion of cutting in the wire electrical discharge machining apparatus 1000 according to the first embodiment. FIG. 12 is an enlarged view illustrating a specific region A in FIG. 11. FIG. 11 illustrates a schematic diagram of a cross section at a position where an outer peripheral side surface Ws of the workpiece W and an outer peripheral side surface 73s of the workpiece power feed assistance portion 73 are in contact with each other just before the end of the cutting into the thin plates. The cross section at the position where the outer peripheral side surface Ws of the workpiece W and the outer peripheral side surface 73s of the workpiece power feed assistance portion 73 are in contact with each other is a cross section in an xz plane passing through the central axis C of the workpiece W. An arrow 83 in FIG. 11 indicates the electrical discharge machining power supply path from the machining fluid flow rectifying plate 71a.

It is assumed that even when the outer peripheral side surface Ws of the workpiece W and the outer peripheral side surface 73s of the workpiece power feed assistance portion 73 are highly accurately polished and flattened, in a structure in which outer peripheral side surfaces of rigid bodies that do not deform abut each other, microscopically, a minute gap is generated in contact portions which are abutting portions. Therefore, it is considered to be difficult to bring the rigid bodies that do not deform into contact with each other over the entire outer peripheral side surfaces thereof. An example of the dimension of the minute gap is about 10 μm or more and 50 μm or less. In addition, depending on the accuracy of the straightness of the workpiece W and the workpiece power feed assistance portion 73 with respect to the facing surface 71as which is the installation surface on the machining fluid flow rectifying plate 71a on which the workpiece W and the workpiece power feed assistance portion 73 are installed and fixed, a minute gap of about 100 μm or more and 300 μm or less, which is larger than the wire diameter of the wire electrode 1 used, may be generated.

When the workpiece power feed assistance portion 73 is in contact, even partially, with the workpiece W, the workpiece power feed assistance portion 73 can energize the workpiece W with the electrical discharge machining power supplied from the machining power supply 5. However, a situation may be assumed in which just before the completion of the cutting into the plurality of thin plates formed from the workpiece W, the electrical discharge machining power supply path from the machining power supply 5 via the machining fluid flow rectifying plate 71a and the workpiece power feed assistance portion 73 is interrupted with respect to the thin plate portion separated from the workpiece W.

An example of a case where the situation is assumed in which the electrical discharge machining power supply path is interrupted as described above is a case where machining by some portions of the wire electrode 1 among the cutting wire parts 1b slightly precedes just before the completion of the cutting into the plurality of thin plates formed from the workpiece W, or a case where a remaining machining portion of the workpiece W that has not yet been cut comes to be much smaller, resulting that mechanical strength of the remaining machining portion is decreased and thus cracking occurs in the thin plates under cutting process.

In the state illustrated in FIGS. 11 and 12, machining by some portions of the wire electrode 1 among the cutting wire parts 1b slightly precedes just before the completion of the cutting into the plurality of thin plates formed from the workpiece W, and the electrical discharge machining power supply path from the machining fluid flow rectifying plate 71a to the workpiece W is interrupted. On the other hand, since the outer peripheral side surface 73s of the workpiece power feed assistance portion 73 and the outer peripheral side surface Ws of the workpiece W are partially in contact with each other, the supply of the electrical discharge machining power from the machining fluid flow rectifying plate 71a to the workpiece W via the workpiece power feed assistance portion 73 is continuously performed.

When the electrical discharge machining power supply path is interrupted just before the completion of the cutting into the plurality of thin plates, the electrical discharge machining is suspended, which provides a thin plate that is not separated due to a presence of a remaining machining portion or a thin plate that cracks at the boundary with the remaining machining portion. In addition, between the electrodes, which is an electrical discharge machining gap in the machining direction, machining slightly precedes a tip of each cutting wire part 1b. Therefore, the thin plates are cut and separated before the cutting wire parts 1b completely pass through the workpiece W. As a result, remaining machining portions remain as minute leftover protrusions at the machining end portions of the separated thin plates, which reduces cutting quality and yield of the thin plates.

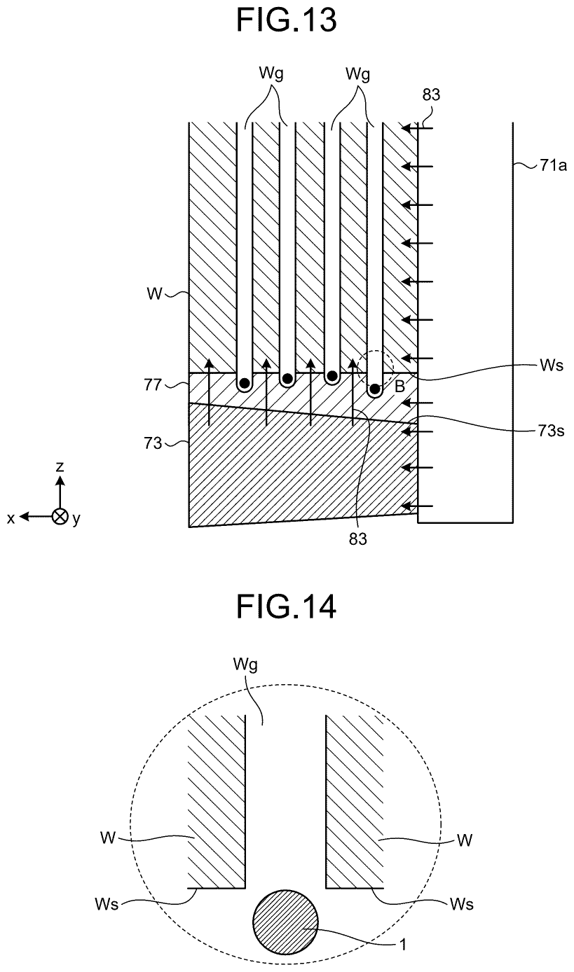

FIG. 13 is a conceptual diagram illustrating an example of a state of thin plates just before the completion of cutting in the wire electrical discharge machining apparatus 1000a according to the second embodiment. FIG. 14 is an enlarged view illustrating a specific region B in FIG. 13. FIG. 13 illustrates a schematic diagram of a cross section at a position where the conductive connecting part 77 and each of the outer peripheral side surface Ws of the workpiece W and the outer peripheral side surface 73s of the workpiece power feed assistance portion 73 are in contact with each other just before the completion of the cutting into the thin plates. The cross section at the position where the conductive connecting part 77 and each of the outer peripheral side surface Ws of the workpiece W and the outer peripheral side surface 73s of the workpiece power feed assistance portion 73 are in contact with each other is a cross section in the xz plane passing through the central axis C of the workpiece W. The arrow 83 in FIG. 13 indicates the electrical discharge machining power supply path from the machining fluid flow rectifying plate 71a.

In FIG. 13, the conductive connecting part 77 provided between the workpiece W and the workpiece power feed assistance portion 73 is sandwiched between the outer peripheral side surface Ws of the workpiece W and the outer peripheral side surface 73s of the workpiece power feed assistance portion 73, and is pressed against the outer peripheral side surface Ws of the workpiece W together with the workpiece power feed assistance portion 73.

The conductive connecting part 77 is deformed by being pressed against the outer peripheral side surface Ws of the workpiece W, and fills a gap between the outer peripheral side surfaces of the workpiece power feed assistance portion 73 and the workpiece W facing each other. Consequently, the contact area between the outer peripheral side surfaces of the workpiece power feed assistance portion 73 and the workpiece W facing each other is enlarged. Consequently, in the wire electrical discharge machining apparatus 1000a, the outer peripheral side surface Ws of the workpiece W and the outer peripheral side surface 73s of the workpiece power feed assistance portion 73 can be brought into complete contact with each other, and conductivity between the workpiece power feed assistance portion 73 and the workpiece W is improved.

In the state illustrated in FIGS. 13 and 14, since the outer peripheral side surface 73s of the workpiece power feed assistance portion 73 and the outer peripheral side surface Ws of the workpiece W are electrically connected via the conductive connecting part 77, the supply of the electrical discharge machining power from the machining fluid flow rectifying plate 71a to the workpiece W via the workpiece power feed assistance portion 73 and the conductive connecting part 77 is continuously performed even after the completion of the cutting into the plurality of thin plates formed from the workpiece W.

As described above, for the conductive connecting part 77, a material, such as a low melting point metal or a porous metal, which has flexibility and a characteristic of being easily deformable is preferably used. Due to the easily deformable characteristic of the conductive connecting part 77, the conductive connecting part 77 pressed against the two outer peripheral side surfaces, i.e., the outer peripheral side surface Ws of the workpiece W and the outer peripheral side surface 73s of the workpiece power feed assistance portion 73 is deformed. Then, the gap between the outer peripheral side surface Ws of the workpiece W and the outer peripheral side surface 73s of the workpiece power feed assistance portion 73 is filled with the conductive connecting part 77 thus deformed, and thereby the contact area between the outer peripheral side surfaces of the workpiece power feed assistance portion 73 and the workpiece W facing each other is enlarged.

Even in a case where contacting portions of the outer peripheral side surface Ws of the workpiece W and the outer peripheral side surface 73s of the workpiece power feed assistance portion 73 are not parallel to each other, the conductive connecting part 77 is deformed to thereby fit in the gap between the outer peripheral side surfaces of the workpiece power feed assistance portion 73 and the workpiece W facing each other, and the gap is filled. Even if there are minute irregularities in the contacting portions of the outer peripheral side surface Ws of the workpiece W and the outer peripheral side surface 73s of the workpiece power feed assistance portion 73, the deformed conductive connecting part 77 fits in a gap caused by the minute irregularities between the outer peripheral side surfaces of the workpiece power feed assistance portion 73 and the workpiece W facing each other, and the gap is filled.

Consequently, in the wire electrical discharge machining apparatus 1000a, the outer peripheral side surface Ws of the workpiece W and the outer peripheral side surface 73s of the workpiece power feed assistance portion 73 can be brought into complete contact with each other, and conductivity between the workpiece power feed assistance portion 73 and the workpiece W is improved. The workpiece power feed assistance portion 73 and the conductive connecting part 77 can constitute, from the start of the cutting to the completion of the cutting, the electrical discharge machining power supply path from the machining fluid flow rectifying plate 71a to the workpiece W and the plurality of thin plates under cutting process. Consequently, the wire electrical discharge machining apparatus 1000a can stably continue the wire cutting of the workpiece W.

In the wire electrical discharge machining apparatus 1000a having the above configuration, even in a case where in the cutting performed at a plurality of portions by the cutting wire parts 1b, the workpiece W is cut by some portions of the wire electrode 1 among the cutting wire parts 1b slightly faster than by other portions of the wire electrode 1 among the cutting wire parts 1b, it is possible to prevent the occurrence of the disruption of the power supply path from the machining power supply 5 to the plurality of thin plates under cutting process, which has occurred in a case where there is no other electrical discharge machining power supply path to the workpiece W and the plurality of thin plates under cutting process than that from the machining fluid flow rectifying plate 71a.

Therefore, in the wire electrical discharge machining apparatus 1000a, the wire electrode 1 constituting the cutting wire parts 1b completely passes through the workpiece W while continuing the cutting with no suspension of the cutting, and reaches the conductive connecting part 77. As a result, in the plurality of thin plates cut by the wire electrical discharge machining apparatus 1000a, leftover protrusions which are remaining machining portions due to suspension of the cutting do not occur at the machining end portions, and the cutting quality and the yield are improved.

As described in the first embodiment, a conductive wax can be used for fixing the workpiece W and the workpiece power feed assistance portion 73 to the machining fluid flow rectifying plate 71a. In a case where such a conductive wax is used for fixing the workpiece W and the workpiece power feed assistance portion 73 to the machining fluid flow rectifying plate 71a, the melting point of a conductive wax for fixing the workpiece W to the machining fluid flow rectifying plate 71a is preferably higher than the melting point of a conductive wax for fixing the workpiece power feed assistance portion 73 to the machining fluid flow rectifying plate 71a. For example, the workpiece W is fixed to the machining fluid flow rectifying plate 71a by using a conductive wax having a melting point of about 60° C., and then the workpiece power feed assistance portion 73, in a state where the outer peripheral surface of the workpiece power feed assistance portion 73 is in contact with the outer peripheral surface of the workpiece W, is fixed to the machining fluid flow rectifying plate 71a by using a conductive wax having a melting point of about 40° C. In a case where the conductive waxes satisfying the above conditions are used, the workpiece W is first fixed to the machining fluid flow rectifying plate 71a, and then the workpiece power feed assistance portion 73 can be fixed to the machining fluid flow rectifying plate 71a, while the outer peripheral side surface 73s of the workpiece power feed assistance portion 73 is reliably brought into contact with the outer peripheral side surface Ws of the workpiece W.

Note that the conductive connecting part 77 may be used between the outer peripheral side surface Ws of the workpiece W and the outer peripheral side surfaces of the thin plate side surface holding portions 75a and 75b.

In addition, in the wire electrical discharge machining apparatus 1000a, the conductive connecting part 77 increases the contact area between the workpiece power feed assistance portion 73 and the workpiece W, the workpiece power feed assistance portion 73 increases a force for holding the workpiece W, and the flow rate of the machining fluid is reduced in the vicinity of the machining end portion where the amount of machining, that is, the cutting length rapidly decreases, and thereby it is possible to perform electrical discharge cutting on the thin plates without damaging the thin plates in the vicinity of the machining end portions. Consequently, in the wire electrical discharge machining apparatus 1000a, the thin plate side surface holding portions 75a and 75b can be omitted.

As described above, the wire electrical discharge machining apparatus 1000a according to the second embodiment has an effect similar to that of the wire electrical discharge machining apparatus 1000 according to the first embodiment described above.

In addition, the wire electrical discharge machining apparatus 1000a includes the conductive connecting part 77 between the outer peripheral side surface Ws of the workpiece W and the outer peripheral side surface 73s of the workpiece power feed assistance portion 73. Consequently, in the wire electrical discharge machining apparatus 1000a, it is possible to increase the contact area between the outer peripheral side surface Ws of the workpiece W and the outer peripheral side surface 73s of the workpiece power feed assistance portion 73, to bring the outer peripheral side surface Ws of the workpiece W and the outer peripheral side surface 73s of the workpiece power feed assistance portion 73 into complete contact with each other, and to improve conductivity between the workpiece power feed assistance portion 73 and the workpiece W. Therefore, in the wire electrical discharge machining apparatus 1000a, it is possible to prevent the occurrence of minute leftover protrusions attributable to the interruption of the electrical discharge machining power supply path just before the completion of the cutting into the plurality of thin plates from the workpiece W, and to improve the cutting quality and the yield of the thin plates.

### Third Embodiment

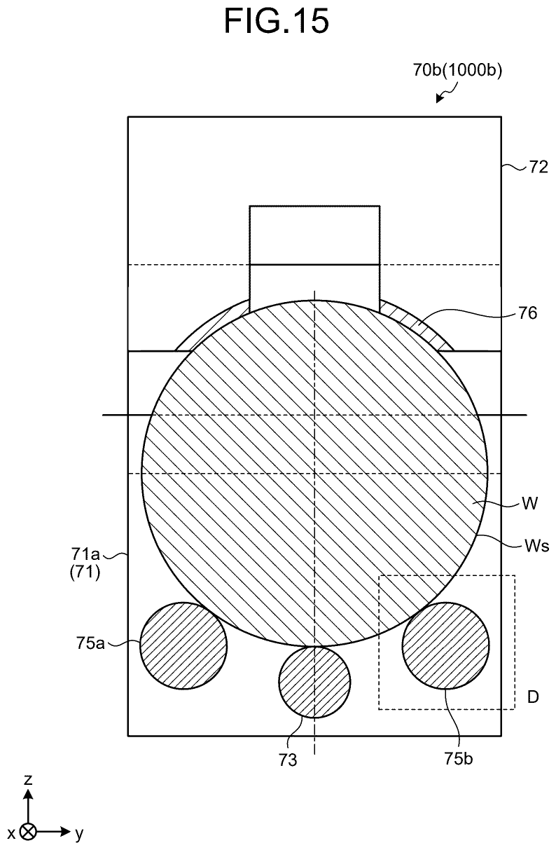

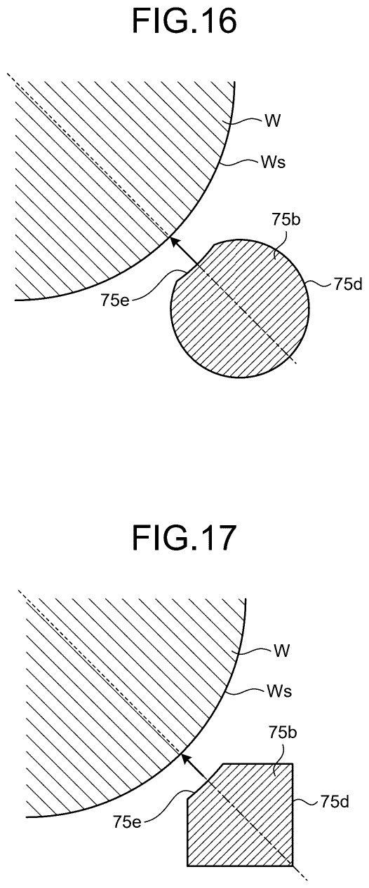

FIG. 15 is a schematic view illustrating an exemplary configuration of the thin plate side surface holding portions 75a and 75b of a thin plate machining stabilization unit 70b included in a wire electrical discharge machining apparatus 1000b according to a third embodiment. FIG. 15 illustrates the machining fluid flow rectifying plate 71a, the workpiece retaining unit 72, the workpiece power feed assistance portion 73, the thin plate side surface holding portions 75a and 75b, and the thin plate portion retainer 76 in the thin plate machining stabilization unit 70b included in the wire electrical discharge machining apparatus 1000b. FIG. 16 is an enlarged view illustrating a specific region D in FIG. 15. FIG. 17 is another enlarged view illustrating the specific region D in FIG. 15. FIG. 16 illustrates a first exemplary shape of the thin plate side surface holding portions 75a and 75b included in the thin plate machining stabilization unit 70b. FIG. 17 illustrates a second exemplary shape of the thin plate side surface holding portions 75a and 75b included in the thin plate machining stabilization unit 70b.

The wire electrical discharge machining apparatus 1000b according to the third embodiment includes the thin plate machining stabilization unit 70b instead of the thin plate machining stabilization unit 70, which is a difference from the wire electrical discharge machining apparatus 1000 according to the first embodiment. In the thin plate machining stabilization unit 70b, the shape of the thin plate side surface holding portions 75a and 75b is different from that of the thin plate side surface holding portions 75a and 75b according to the first embodiment.

The rest of the configuration of the wire electrical discharge machining apparatus 1000b according to the third embodiment is similar to that of the wire electrical discharge machining apparatus 1000 according to the first embodiment, and a redundant description will not be repeated.

The thin plate side surface holding portions 75a and 75b installed in the machining path of the workpiece W have a function of preventing shaking of the plurality of thin plates formed from the workpiece W due to a force received from the machining fluid flow, and a function of supplying electrical discharge machining power to each thin plate. Therefore, regarding a state of contact between the workpiece W and the thin plate side surface holding portions 75a and 75b, surface contact is more advantageous than line contact from the viewpoint of improvement in a force for holding the thin plates and stable power supply to the thin plates. That is, by adjusting the state of contact between the workpiece W and the thin plate side surface holding portions 75a and 75b to surface contact, the contact area between the workpiece W and each of the thin plate side surface holding portions 75a and 75b is enlarged, and the state of the thin plates during cutting held by the thin plate side surface holding portions 75a and 75b is further stabilized. By the state of the thin plates during cutting held by the thin plate side surface holding portions 75a and 75b being further stabilized, it is possible to perform the cutting while increasing the electrical discharge machining speed, and the cutting quality is improved.

Therefore, a contact surface 75e on an outer peripheral side surface 75d of each of the thin plate side surface holding portions 75a and 75b to be in contact with the outer peripheral side surface Ws of the workpiece W preferably has a shape formed along the shape of the outer peripheral side surface Ws of the workpiece W. Regarding the contact surface 75e where the outer peripheral side surface 75d of each of the thin plate side surface holding portions 75a and 75b is in contact with the outer peripheral side surface Ws of the workpiece W, when the length of the contact surface 75e in the circumferential direction of the outer peripheral side surface Ws of the workpiece W is about 3 mm, the reliability of the force for holding the thin plates and the stable power supply to each thin plate is improved.

The thin plate side surface holding portion 75b in the first exemplary shape illustrated in FIG. 16 has a columnar shape in which a shape thereof in a planar direction perpendicular to the x-axis direction is a circular shape, and a shape of the contact surface 75e in contact with the outer peripheral side surface Ws of the workpiece W in the planar direction perpendicular to the x-axis direction is formed into an arc shape which is a shape formed along the shape of the outer peripheral side surface Ws of the workpiece W. In the thin plate side surface holding portion 75b in the first exemplary shape configured as described above, the state of contact with the workpiece W is surface contact on the contact surface 75e. Therefore, the thin plate side surface holding portion 75b in the first exemplary shape is excellent from the viewpoint of the force for holding the thin plates and the stable power supply to the thin plates as compared with the thin plate side surface holding portion 75b in which the state of contact with the workpiece W is line contact. Although the thin plate side surface holding portion 75b has been described here, the same applies to the thin plate side surface holding portion 75a and the workpiece power feed assistance portion 73.

The thin plate side surface holding portion 75b in the second exemplary shape illustrated in FIG. 17 has a rectangular column shape or a prismatic column shape in which a shape thereof in a planar direction perpendicular to the x-axis direction is a square shape, and a shape of the contact surface 75e in contact with the outer peripheral side surface Ws of the workpiece W in the planar direction perpendicular to the x-axis direction is formed into an arc shape which is a shape formed along the shape of the outer peripheral side surface Ws of the workpiece W. In the thin plate side surface holding portion 75b in the second exemplary shape configured as described above, the state of contact with the workpiece W is surface contact on the contact surface 75e. Therefore, the thin plate side surface holding portion 75b in the second exemplary shape is excellent from the viewpoint of the force for holding the thin plates and the stable power supply to the thin plates as compared with the thin plate side surface holding portion 75b in which the state of contact with the workpiece W is line contact. Although the thin plate side surface holding portion 75b has been described here, the same applies to the thin plate side surface holding portion 75a.

The material used for the thin plate side surface holding portions 75a and 75b is preferably a material having electrical discharge machining characteristics similar to those of the workpiece W. For example, in a case where the workpiece W made of Sic is cut, the thin plate side surface holding portions 75a and 75b are preferably constituted with silicon carbide or a sintered member of silicon carbide powder. By machining a bulk obtained by sintering the SiC powder to manufacture the thin plate side surface holding portions 75a and 75b, a material cost of the thin plate side surface holding portions 75a and 75b can be reduced.

A consideration was given to a case where standard metal such as copper, brass, iron, or aluminum is used for the thin plate side surface holding portions 75a and 75b when performing cutting of the thin plates from the workpiece W made of a material such as silicon carbide or gallium nitride, and a case where sintered silicon carbide is used for the thin plate side surface holding portions 75a and 75b when performing the cutting. As a result, it has been confirmed in machining experiments by the present inventors that, in the case where sintered silicon carbide is used for the thin plate side surface holding portions 75a and 75b, damage to the wire electrode 1 by the electrical discharge machining is extremely small from the amount of wear of the wire electrode 1 due to the electrical discharge machining and a change in the electrical discharge machining characteristics caused by reattachment of machining debris generated by the electrical discharge machining to the surface of the wire electrode 1.

However, among materials, silicon carbide and gallium nitride have relatively high hardness, are easily chipped by impact, and are difficult-to-machine materials that are difficult to machine in shaving. Therefore, the thin plate side surface holding portions 75a and 75b made of silicon carbide are formed by performing cutting from a bulk member by using wire electrical discharge machining, which is a machining method that can easily perform highly accurate shape machining on the basis of machining loci by an NC program, is non-contact thermal machining, and is not affected by the hardness or brittleness of a material. The thin plate side surface holding portions 75a and 75b made of silicon carbide or gallium nitride are used for cutting of the workpiece W made of a semiconductor material such as silicon carbide, gallium nitride, silicon (Si), or gallium oxide (Ga₂O₃) into a plurality of thin plates by electrical discharge machining by the cutting wire parts 1b.

As described above, in the wire electrical discharge machining apparatus 1000b according to the third embodiment, the contact surface 75e on the outer peripheral side surface 75d of each of the thin plate side surface holding portions 75a and 75b to be in contact with the outer peripheral side surface Ws of the workpiece W has a shape formed along the shape of the outer peripheral side surface Ws of the workpiece W. That is, the contact surface 75e has a shape formed along the shape of the outer peripheral side surface Ws of the workpiece W, which is a concave shape that corresponds to a convex shape of the outer peripheral side surface Ws of the workpiece W. Consequently, in the wire electrical discharge machining apparatus 1000b, the contact area between the workpiece W and each of the thin plate side surface holding portions 75a and 75b is enlarged, the state of the thin plates during cutting held by the thin plate side surface holding portions 75a and 75b is further stabilized, and the electrical discharge machining speed and the cutting quality are improved.

Next, a hardware configuration of the control unit 300 according to the first to third embodiments will be described. Functions of the control unit 300 included in each of the wire electrical discharge machining apparatuses 1000, 1000a, and 1000b are realized by a processing circuitry. The processing circuitry is dedicated hardware mounted on the control unit 300 of each of the wire electrical discharge machining apparatuses 1000, 1000a, and 1000b. The processing circuitry may be a processor that executes a program stored in a memory.

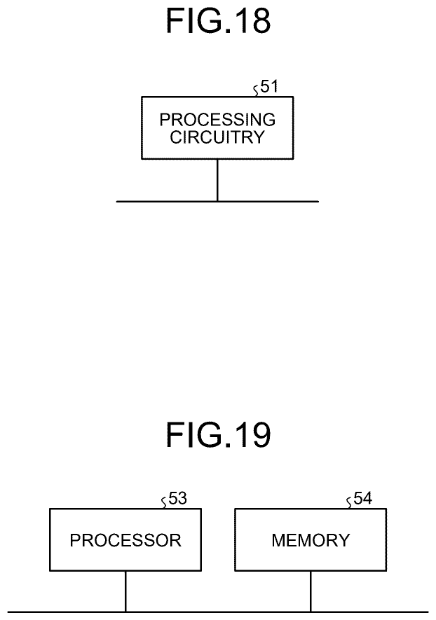

FIG. 18 is a diagram illustrating a hardware configuration in a case where functions of the control unit 300 included in each of the wire electrical discharge machining apparatuses 1000, 1000a, and 1000b are realized by dedicated hardware. A processing circuitry 51 as dedicated hardware is a single circuit, a composite circuit, a programmed processor, a parallel programmed processor, an application specific integrated circuit (ASIC), a field-programmable gate array (FPGA), or a combination thereof.

FIG. 19 is a diagram illustrating a hardware configuration in a case where the functions of the control unit 300 included in each of the wire electrical discharge machining apparatuses 1000, 1000a, and 1000b illustrated in FIG. 18 are realized by a processor that executes a program stored in a memory. A processor 53 and a memory 54 are communicably connected to each other. The processor 53 is a central processing unit (CPU), a processing device, an arithmetic device, a microprocessor, a microcomputer, or a digital signal processor (DSP). The functions of the control unit 300 are realized by the processor 53, and software, firmware, or a combination of software and firmware. The software or the firmware is described as a program and stored in the memory 54. The memory 54 is a built-in memory, for example, a nonvolatile or volatile semiconductor memory such as a random access memory (RAM), a read only memory (ROM), a flash memory, an erasable programmable read only memory (EPROM), or an electrically erasable programmable read only memory (EEPROM (registered trademark)).

A part of the functions of the control unit 300 may be realized by dedicated hardware, and another part of the functions of the control unit 300 may be realized by software or firmware. Thus, the functions of the control unit 300 can be realized by hardware, software, firmware, or a combination thereof.

The configurations described in the above embodiments are merely examples and can be combined with other known technology, the embodiments can be combined with each other, and part of the configurations can be omitted or modified without departing from the gist thereof.

### REFERENCE SIGNS LIST

1 wire electrode; 1a parallel wire part; 1b cutting wire part; 2, 2a, 2b, 2c, 2d guide roller; 2e guide groove; 3, 3a, 3b bobbin; 4a, 4b damping guide roller; 5 machining power supply; 6a, 6b power feed contact unit; 7a, 7b nozzle; 7c machining fluid ejection hole; 8a, 8b bobbin rotation control device; 9a, 9b traverse control device; 10 cutting feed stage; 31 machining control device; 32 electrical discharge waveform control device; 33 machining state acquisition unit; 34 cutting stage drive control device; 35 wire running control device; 36 workpiece retaining unit holding control device; 51 processing circuitry; 53 processor; 5 memory; 70, 70a, 70b thin plate machining stabilization unit; 71, 71a, 71b machining fluid flow rectifying plate; 71as, 71bs facing surface; 72 workpiece retaining unit; 72a groove portion; 73 workpiece power feed assistance portion; 73s, 75d, Ws outer peripheral side surface; 74 machining fluid supply pipe; 75a, 75b thin plate side surface holding portion; 75c thin plate portion; 75e contact surface; 75g, 77g machined groove; 76 thin plate portion retainer; 77 conductive connecting part; 78 workpiece retaining unit holding device; 100 machining mechanism unit; 200 power feed unit; 300 control unit; 1000, 1000a, 1000b wire electrical discharge machining apparatus; A, B, D specific region; C central axis; PD diameter portion position; PE machining end position; PH machining position; PS machining start position; W workpiece; Wg machined groove.

1. A wire electrical discharge machining apparatus that generates electrical discharge between a plurality of cutting wire parts that are running and a workpiece to perform electrical discharge machining on the workpiece with energy generated by the electrical discharge, and simultaneously cuts out a plurality of wafers from the workpiece, the wire electrical discharge machining apparatus comprising:
a wire electrode including the plurality of cutting wire parts spaced apart from each other in parallel and facing the workpiece;
a machining power supply to generate electrical discharge between the plurality of cutting wire parts and the workpiece;
a pair of machining fluid flow rectifying plates having conductivity connected to the machining power supply and provided in contact with both sides of the workpiece so as to sandwich the workpiece;
a pair of nozzles in which the plurality of cutting wire parts are inserted, the pair of nozzles including a plurality of machining fluid ejection holes that eject a machining fluid toward a space sandwiched between the pair of machining fluid flow rectifying plates to supply the machining fluid to a gap between the plurality of cutting wire parts and the workpiece;
a cutting feed stage to move the pair of machining fluid flow rectifying plates upward and downward relative to the plurality of cutting wire parts;
a workpiece retaining unit to hold the workpiece to be divided during cutting from above the workpiece and the plurality of cutting wire parts; and
a lower workpiece holding portion having conductivity to come into contact with the workpiece from below to hold the workpiece, wherein
the pair of machining fluid flow rectifying plates comprises:
a first machining fluid flow rectifying plate provided so as to be in contact with one end surface of the workpiece in a wire parallel direction that is a direction in which the cutting wire parts are disposed in parallel, and connected to the machining power supply; and
a second machining fluid flow rectifying plate provided so as to be in contact with another end surface of the workpiece in the wire parallel direction,
the lower workpiece holding portion is fixed to a facing surface of the first machining fluid flow rectifying plate, the facing surface being a surface of the first machining fluid flow rectifying plate facing the second machining fluid flow rectifying plate, and
the lower workpiece holding portion comprises:
a thin plate side surface holding portion provided over upper and lower regions of a machining end portion that is a portion where cutting of the workpiece by the cutting wire parts is completed in an upward and downward direction thereof and fixed to the first machining fluid flow rectifying plate in a state of being in contact with an outer peripheral side surface of the workpiece.

2. (canceled)

3. The wire electrical discharge machining apparatus according to claim 1, wherein the lower workpiece holding portion comprises:
a workpiece power feed assistance portion fixed to the first machining fluid flow rectifying plate in a state of being in contact with an outer peripheral side surface of a machining end portion that is a portion where cutting of the workpiece by the cutting wire parts is completed.

4. The wire electrical discharge machining apparatus according to claim 3, wherein
the workpiece power feed assistance portion is disposed just below the machining end portion.

5. The wire electrical discharge machining apparatus according to claim 3, comprising:
a conductive connecting part having flexibility disposed to be sandwiched between the workpiece power feed assistance portion or the thin plate side surface holding portion and the workpiece, and filling a gap between the workpiece power feed assistance portion or the thin plate side surface holding portion and the workpiece.

6. The wire electrical discharge machining apparatus according to claim 5, wherein
the conductive connecting part is constituted with a flexible conductive material having a Young's modulus of 80 Gpa or less and an electric resistance value of 10 Ωcm or less.

7. The wire electrical discharge machining apparatus according to claim 3, wherein in a cutting direction of the workpiece, a contact position of an outer peripheral side surface of the thin plate side surface holding portion with respect to the outer peripheral side surface of the workpiece is located in a section in which when cutting proceeds to the contact position, an uncut length that is a length of the workpiece being not yet cut is ½ or less of an entire cutting length of the workpiece, the section being located at a position above a position where an outer peripheral side surface of the workpiece power feed assistance portion is in contact with the outer peripheral side surface of the workpiece.

8. The wire electrical discharge machining apparatus according to claim 7, wherein the thin plate side surface holding portion is cut together with the workpiece, and a plurality of thin plate portions of the thin plate side surface holding portion formed by cutting of the thin plate side surface holding portion support and fix a plurality of wafers formed by being cut from the workpiece simultaneously with the thin plate portions and separated from each other.

9. The wire electrical discharge machining apparatus according to claim 1, wherein
the thin plate side surface holding portion includes silicon carbide or a sintered member of silicon carbide powder.

10. The wire electrical discharge machining apparatus according to claim 1, comprising:
an attitude changing mechanism that changes attitudes of the first machining fluid flow rectifying plate and the second machining fluid flow rectifying plate to be relatively rotated with respect to the cutting wire parts or to be relatively inclined with respect to the cutting wire parts, and fixes the first machining fluid flow rectifying plate and the second machining fluid flow rectifying plate.

11. A wire electrical discharge machining method for generating electrical discharge between a plurality of cutting wire parts that are running and a workpiece to perform electrical discharge machining on the workpiece with energy generated by the electrical discharge, and simultaneously cutting out a plurality of wafers from the workpiece, the wire electrical discharge machining method comprising:
ejecting a machining fluid from a nozzle toward a space sandwiched between a pair of machining fluid flow rectifying plates connected to a machining power supply, guiding a flow of the machining fluid to the workpiece by facing surfaces of the pair of machining fluid flow rectifying plates, and supplying the machining fluid to a gap between the plurality of cutting wire parts and the workpiece;
holding the workpiece to be divided during cutting from above the workpiece and the plurality of cutting wire parts; and
in a state where a lower workpiece holding portion having conductivity comes into contact with the workpiece from below to hold the workpiece during cutting of the workpiece, the lower workpiece holding portion being provided over upper and lower regions of a machining end portion that is a portion where cutting of the workpiece is completed in a cutting direction of the workpiece and fixed to the facing surface of one of the pair of machining fluid flow rectifying plates, supplying power from the pair of machining fluid flow rectifying plates to the workpiece via the lower workpiece holding portion, from start of cutting of the workpiece to end of cutting of the workpiece.

12. The wire electrical discharge machining method according to claim 11, wherein
the pair of machining fluid flow rectifying plates comprises:
a first machining fluid flow rectifying plate provided so as to be in contact with one end surface of the workpiece in a wire parallel direction that is a direction in which the cutting wire parts are disposed in parallel, and connected to the machining power supply; and
a second machining fluid flow rectifying plate provided so as to be in contact with another end surface of the workpiece in the wire parallel direction, and
the lower workpiece holding portion comprises:
a workpiece power feed assistance portion fixed to the first machining fluid flow rectifying plate in a state of being in contact with an outer peripheral side surface of a machining end portion that is a portion where cutting of the workpiece by the cutting wire parts is completed; and
a thin plate side surface holding portion provided over upper and lower regions of the machining end portion in an upward and downward direction and fixed to the first machining fluid flow rectifying plate in a state of being in contact with an outer peripheral side surface of the workpiece.

13. A wafer manufacturing method comprising:
simultaneously cutting out a plurality of wafers from the workpiece by the wire electrical discharge machining method according to claim 11.

14. The wafer manufacturing method according to claim 13, wherein
the workpiece is a semiconductor ingot, and
the wafer is a semiconductor wafer.

15. The wire electrical discharge machining apparatus according to claim 4, comprising:
a conductive connecting part having flexibility disposed to be sandwiched between the workpiece power feed assistance portion or the thin plate side surface holding portion and the workpiece, and filling a gap between the workpiece power feed assistance portion or the thin plate side surface holding portion and the workpiece.

16. The wire electrical discharge machining apparatus according to claim 15, wherein
the conductive connecting part is constituted with a flexible conductive material having a Young's modulus of 80 Gpa or less and an electric resistance value of 10 Ωcm or less.

17. A wafer manufacturing method comprising:
simultaneously cutting out a plurality of wafers from the workpiece by the wire electrical discharge machining method according to claim 12.

18. The wafer manufacturing method according to claim 17, wherein
the workpiece is a semiconductor ingot, and
the wafer is a semiconductor wafer.
